(19) United States
(12) Patent Application Publication
(10) Pub. No.: US 2022/0404439 A1
(43) Pub. Date: Dec. 22, 2022

(54) INFORMATION PROCESSING DEVICE AND MAGNETIC SENSOR SYSTEM

(71) Applicant: SHOWA DENKO K.K., Tokyo (JP)

(72) Inventor: Hiroyuki TOMITA, Ichihara-shi (JP)

(73) Assignee: SHOWA DENKO K.K., Tokyo (JP)

(21) Appl. No.: 17/845,594

(22) Filed: Jun. 21, 2022

(30) Foreign Application Priority Data
Jun. 22, 2021 (JP) 2021-103331

(51) Int. Cl. G01R 33/06

(52) U.S. Cl. CPC G01R 33/063

(57) ABSTRACT

An information processing device and a magnetic sensor system are provided, in which accuracy of frequency measurement is less likely to deteriorate even though the frequency of output signals outputted from the magnetic sensor increases, and which have detection limits for high frequency measurement even with a minute frequency change rate. An information processing device 120 includes: an obtaining part 31 obtaining an output signal outputted by a magnetic sensor and oscillating at a frequency determined in response to strength of a magnetic field; a frequency determination part 32 utilizing interference between the output signal and a reference signal with a reference frequency, which is a frequency used as a reference, to determine the frequency of the output signal; and a magnetic field calculation part 40 calculating the strength of the magnetic field based on the determined frequency of the output signal.

### CROSS REFERENCE TO RELATED APPLICATIONS

This application is based on and claims priority under 35 USC § 119 to Japanese Patent Application No. 2021-103331 filed Jun. 22, 2021, the disclosure is incorporated herein by reference in its entirety.

### BACKGROUND

### Technical Field

The present invention relates to an information processing device and a magnetic sensor system.

### Related Art

As a related art described in a gazette, in a magnetic field sensor with two CMOS inverters, amorphous wires connected in series with resistors, and a multi-vibrator oscillation circuit configured with a capacitance, there is a frequency-modulated magnetic field sensor in which a power supply voltage is set to not more than 3V and a series resistance of a resistor R and an amorphous wire is set to not more than 500Ω, and the duration during which the input voltage of the two CMOS inverters is held at the threshold voltage is changed by an externally applied magnetic field (refer to Japanese Patent Application Laid-Open Publication No. 2004-108778).

For example, in a magnetic sensor using a magnetic impedance effect element as a sensitive element that senses a magnetic field, an alternating current is supplied to the sensitive element to detect the magnetic field from change in impedance in the sensitive element. On this occasion, the change in impedance at the sensitive element is detected by the change in frequency of the sensitive element in some cases.

In the magnetic impedance effect element, the impedance changes sensitively in the external magnetic field due to the skin effect of a high magnetic permeability alloy magnetic material. In the skin effect, the depth of the surface layer through which the current flows (skin depth δ) is expressed as δ=√(2ρ/ωμ) (ρ: electrical resistivity, ω: angular frequency of flowing current, μ: maximum differential magnetic permeability perpendicular to flowing current), and therefore, the higher the frequency, the thinner the δ and the larger the change in the impedance. Consequently, as the frequency becomes higher, the sensitivity of the magnetic sensor using the magnetic impedance effect element is likely to increase.

However, if the frequency of the output signal outputted from the sensitive element increases, the sampling rate when measures the frequency is insufficient, and thereby the accuracy of the frequency measurement decreases in some cases.

In addition, in the case of detecting a minute magnetic field, the change in frequency to be obtained becomes smaller, and at a limited sampling rate, the frequency resolution is sometimes insufficient to detect the change in the magnetic field. Therefore, it is desirable to increase the frequency change rate by external magnetic fields to improve the detection limit in the frequency measurement.

The present invention provides an information processing device and a magnetic sensor system in which accuracy of frequency measurement is less likely to deteriorate even though the frequency of output signals outputted from the magnetic sensor increases, and which have detection limits for high frequency measurement even with a minute frequency change rate.

### SUMMARY

Thus, according to the present invention, there is provided an information processing device including: an obtaining part obtaining an output signal outputted by a magnetic sensor and oscillating at a frequency determined in response to strength of a magnetic field; a frequency determination part utilizing interference between the output signal and a reference signal with a reference frequency, which is a frequency used as a reference, to determine the frequency of the output signal; and a magnetic field calculation part calculating the strength of the magnetic field based on the determined frequency of the output signal.

Here, as a result of the interference, the frequency determination part may reduce the frequency of the output signal to a low frequency while maintaining an amount of change in the frequency to improve a rate of change in the frequency, and may use the low frequency to determine the frequency of the output signal.

In addition, as a result of the interference, the frequency determination part may determine the frequency of the output signal from a waveform obtained based on a phase difference between the output signal and the reference signal.

Further, the frequency determination part may determine the frequency of the output signal based on a triangular wave generated by averaging the waveform with respect to time.

Still further, the frequency determination part may cause the output signal having been integrated and averaged and the reference signal to interfere with each other to generate the triangular wave.

The frequency determination part may use plural frequencies as the reference frequency and may cause the output signal and the reference signal to interfere with each other to generate the triangular wave.

Moreover, the interference may be caused by at least one of a logic operation and a phase frequency comparator.

Further, the frequency determination part may cause the interference by mixing the output signal and the reference signal by a superheterodyne system.

Still further, the frequency determination part may utilize aliasing caused by interference between the output signal and the reference signal to determine the frequency of the output signal.

The frequency determination part may change a sampling frequency, as the reference signal, for the output signal to cause the interference.

In addition, the frequency determination part may use a D-flip-flop to cause the interference.

Moreover, the frequency determination part may use a sampling clock signal at a digital signal input port to cause the interference.

Moreover, according to the present invention, there is provided a magnetic sensor system including: a magnetic sensor including a delay generation part serially connecting a sensitive element sensing a magnetic field by a magnetic impedance effect and a capacitive element, and a potential supply part connected to the delay generation part and supplying a potential to cause an alternating current, whose frequency is set by the delay generation part, to flow to the delay generation part, the magnetic sensor outputting the alternating current as an output signal; a frequency determination part utilizing interference between the output signal and a reference signal with a reference frequency, which is a frequency used as a reference, to determine the frequency of the output signal; and a magnetic field calculation part calculating strength of a magnetic field based on the determined frequency of the output signal.

According to the present invention, it is possible to provide an information processing device and a magnetic sensor system in which accuracy of frequency measurement is less likely to deteriorate even though the frequency of output signals outputted from the magnetic sensor increases, and which have detection limits for high frequency measurement even with a minute frequency change rate.

### BRIEF DESCRIPTION OF THE DRAWINGS

Exemplary embodiments of the present invention will be described in detail based on the following figures, wherein:

FIG. 1 illustrates a magnetic sensor system to which a first exemplary embodiment is applied;

FIGS. 2A and 2B illustrate an example of a sensitive element, where FIG. 2A is a plan view of the sensitive element and FIG. 2B is a cross-sectional view of the sensitive element along the IIB-IIB line in FIG. 2A;

FIGS. 3A to 3D show electrical characteristics of the sensitive element with respect to a magnetic field, where FIG. 3A illustrates a relation between the magnetic field applied in the longitudinal direction of a sensitive part in the sensitive element and an impedance of the sensitive element, FIG. 3B illustrates a relation between the magnetic field applied in the longitudinal direction of the sensitive part in the sensitive element and a resistance of the sensitive element, FIG. 3C illustrates a relation between the magnetic field applied in the longitudinal direction of the sensitive part in the sensitive element and a reactance of the sensitive element, and FIG. 3D illustrates a relation between the magnetic field applied in the longitudinal direction of the sensitive part in the sensitive element and an inductance of the sensitive element;

FIGS. 4A to 4C illustrate a magnetic sensor to which the first exemplary embodiment is applied, where FIG. 4A shows an equivalent circuit indicated by logical symbols, FIG. 4B shows an equivalent circuit indicated by the transistors, and FIG. 4C is an equivalent circuit that is the deformation of the circuit shown in FIG. 4B;

FIGS. 5A to 5D show diagrams illustrating operations of the magnetic sensor to which the first exemplary embodiment is applied in the case where a frequency setting part is an RC series circuit, where FIG. 5A shows the equivalent circuit of the magnetic sensor shown in FIG. 4C, FIG. 5B shows a timing chart for each potential at the points α, β and γ based on the ground potential, FIG. 5C shows a timing chart for each potential at the points α and β based on the potential at the point γ, and FIG. 5D shows a timing chart for each potential at the points β and γ based on the potential at the point α;

FIG. 6 shows a conceptual diagram of a circuit configuration that uses logical operations to cause the output signal and the reference signal interfere with each other;

FIGS. 7A to 7E show operations of a logical operation part and a triangular wave generation part;

FIG. 8 shows a conceptual diagram of a circuit configuration that uses a superheterodyne system to mix the output signal and the reference signal;

FIG. 9 shows a conceptual diagram of a circuit configuration that utilizes aliasing to determine the frequency of the output signal;

FIGS. 10A to 10E are diagrams showing the aliasing for analogue signals;

FIGS. 11A to 11E are diagrams showing the aliasing for digital signals;

FIG. 12A shows results of measuring the output frequency and variation thereof in the aliasing for the digital signals in the case where the sampling frequency is 300 MHz and the input signal frequency is changed from 270 MHz to 299.9997 MHz, and FIG. 12B shows the frequency error and variation with respect to the difference between the sampling frequency and the input frequency in the measurement in the above-described FIG. 12A.

### DETAILED DESCRIPTION

Hereinafter, exemplary embodiments according to the present invention will be described with reference to attached drawings.

### (Magnetic Sensor System 100)

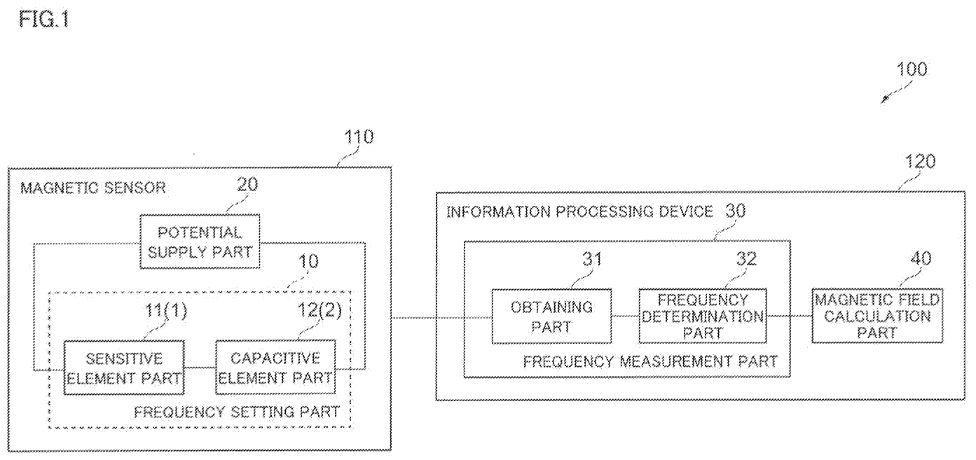

FIG. 1 illustrates a magnetic sensor system 100 to which a first exemplary embodiment is applied. The magnetic sensor system 100 is provided with a magnetic sensor 110 and an information processing device 120.

The magnetic sensor 110 is an oscillation circuit whose frequency changes due to changes in the characteristics of sensitive elements 1 due to an external magnetic field, and various types of oscillation circuits can be used. For example, an LC resonance circuit configured with the inductance of the sensitive element 1 and the capacitive element can be used for the magnetic sensor 110 because, when the inductance of the sensitive element 1 changes in the external magnetic field, the LC resonance frequency changes and thereby the oscillatory frequency changes. In addition, the delay time caused in an RLC series circuit, which combines the resistance and inductance of the sensitive element 1 and the capacitive element, changes because the resistance and inductance of the sensitive element 1 in the external magnetic field change. A relaxation oscillation circuit utilizing the change in the delay time can also be used for the magnetic sensor 110 because the oscillation frequency changes in the external magnetic field. As shown in FIG. 1, the magnetic sensor 110 includes a frequency setting part 10 and a potential supply part 20 that supplies a voltage to the frequency setting part 10. The frequency setting part 10 is provided with a sensitive element part 11 that includes the sensitive elements 1 using the so-called magnetic impedance effect, and a capacitive element part 12 that includes the capacitive elements 2. Note that the capacitive element 2 is an element that accumulates electric charges and is sometimes called a condenser or a capacitor.

The sensitive element part 11 is connected in series with the capacitive element part 12. The sensitive element 1 can be represented by an equivalent circuit in which the resistance and the inductance are connected in series, and each of the resistance and the inductance changes in response to the change in the external magnetic field. The RLC series circuit is formed by connecting the sensitive element part 11 and the capacitive element part 12 in series. Note that, in the exemplary embodiment, the sensitive element part 11 and the capacitive element part 12 function as an example of a delay generation part.

In the frequency setting part 10, the capacitive elements 2 in the capacitive element part 12 repeat the charge and discharge via the sensitive element part 11, and thereby the alternating current flows through the sensitive elements 1 in the sensitive element part 11. On this occasion, in the sensitive element 1, the resistance and the inductance change due to the magnetic field or the change in the magnetic field. Consequently, in the frequency setting part 10, the cycle of the capacitive element 2 repeatedly charging and discharging changes. In other words, the frequency of the alternating current flowing through the sensitive element 1 changes.

In addition to the sensitive elements 1, the sensitive element part 11 may also include other electronic elements, such as resistive elements and inductance elements, that are connected in series or in parallel. In addition to the capacitive elements 2, the capacitive element part 12 may also include other electronic elements, such as resistive elements and inductance elements, that are connected in series or in parallel. Hereinafter, for simplifying the explanation, the description will be given assuming that the sensitive element part 11 is configured with the sensitive elements 1, and the capacitive element part 12 is configured with the capacitive elements 2. Then, the sensitive element part 11 is represented as the sensitive element 1, and the capacitive element part 12 is represented as the capacitive element 2. In other words, the sensitive element 1 is the sensitive element part 11, and the capacitive element 2 is the capacitive element part 12. In FIG. 1, the sensitive element part 11 is denoted as 11 (1), and the capacitive element part 12 is denoted as 12 (2).

The information processing device 120 processes the alternating current flowing through the magnetic sensor 110 to obtain the strength of the magnetic field.

The information processing device 120 includes a frequency measurement part 30 that measures the frequency of the alternating current flowing through the magnetic sensor 110, and a magnetic field calculation part 40 that calculates the magnetic field or the change in the magnetic field sensed by the sensitive element 1, which will be described later, based on the frequency measured by the frequency measurement part 30.

The frequency measurement part 30 measures the frequency of the alternating current emitted from the magnetic sensor 110, and outputs thereof to the magnetic field calculation part 40. As shown in the figure, the frequency measurement part 30 includes an obtaining part 31 and a frequency determination part 32. Details of the frequency measurement part 30 will be described later.

The magnetic field calculation part 40 calculates the magnetic field or the change in the magnetic field that is sensed by the sensitive element 1 based on the frequency determined by the frequency measurement part 30. The magnetic field calculation part 40 stores the relationship between the resistance and inductance of the sensitive element 1 and the strength of the magnetic field to be sensed. Therefore, the magnetic field calculation part 40 calculates the impedance of the sensitive element 1 from the frequency measured by the frequency measurement part 30, and calculates the magnetic field or the change in the magnetic field that is to be sensed by the sensitive element 1 based on the impedance.

### (Configuration of Sensitive Element 1)

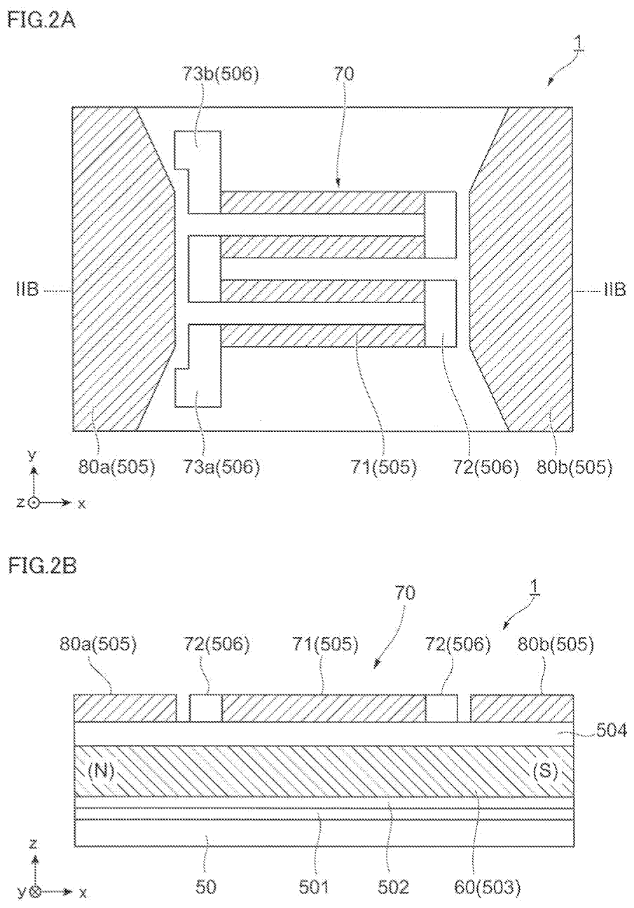

FIGS. 2A and 2B illustrate an example of the sensitive element 1. FIG. 2A is a plan view of the sensitive element 1, and FIG. 2B is a cross-sectional view of the sensitive element 1 along the IIB-IIB line in FIG. 2A. In FIG. 2A, it is assumed that the right direction of the page is the x direction, the upward direction of the page is the y direction, and the front side direction of the page is the z direction. In FIG. 2B, it is assumed that the right direction of the page is the x direction, the upward direction of the page is the z direction, and the backside direction of the page is the y direction.

As shown in FIG. 2B, the sensitive element 1 includes: a thin film magnet 60 configured with a hard magnetic material (a hard magnetic material layer 503) provided on a substrate 50 made of a non-magnetic material; a sensitive circuit 70 laminated to face the thin film magnet 60 to sense the magnetic field; and yokes 80.

Note that a cross-sectional structure of the sensitive element 1 will be described in detail later.

Here, a soft magnetic material in the magnetic material has a small, so-called coercive force, the soft magnetic material being easily magnetized by an external magnetic field, but, upon removal of the external magnetic field, quickly returning to a state with no magnetization or a little magnetization. The hard magnetic material in the magnetic material has a large, so-called coercive force, the hard magnetic material being once magnetized by an external magnetic field, even upon removal of the external magnetic field, maintaining the magnetized state.

Note that, in the present specification, an element constituting the sensitive element 1 (the thin film magnet 60 or the like) is indicated by a two-digit number, and a layer processed into an element (the hard magnetic material layer 503 or the like) is indicated by a number in the five hundreds. Then, for an element, a layer processed into the element is written in parentheses. For example, the case of the thin film magnet 60 is written as the thin film magnet 60 (hard magnetic material layer 503). In the figure, the case is written as 60 (503). In addition, for a layer processed into an element, the element is written in parentheses. For example, the case of the hard magnetic material layer 503 is written as the hard magnetic material layer 503 (thin film magnet 60). The same is true in other cases.

With reference to FIG. 2A, the planar structure of the sensitive element 1 will be described. The sensitive element 1 has a quadrangular planar shape, as an example. Here, the sensitive circuit 70 and the yokes 80 formed at an uppermost portion of the sensitive element 1 will be described. The planar shape of the sensitive element 1 is several millimeters square. Note that the size of the sensitive element 1 may be other values.

The sensitive circuit 70 includes: plural sensitive parts 71 configured with the soft magnetic materials (a soft magnetic material layers 505); connection parts 72 each serially connecting sensitive parts 71 windingly; and terminal parts 73 provided at one end portion and the other end portion of the sensitive parts 71 that are connected in series.

The sensitive part 71 has a reed-shaped planar shape with a longitudinal direction and a short direction. It is assumed that, in the sensitive part 71 shown in FIG. 2A, the x direction is the longitudinal direction, and the y direction is the short direction. Then, in FIG. 2A, four sensitive parts 71 are disposed in parallel in the y direction. The sensitive part 71 shows the magnetic impedance effect. Accordingly, the sensitive element 1 is sometimes referred to as a magnetic impedance element.

Each sensitive part 71 has, for example, the length in the longitudinal direction of 1 mm to 10 mm, and the width in the short direction of 50 μm to 150 μm. The thickness of the sensitive part 71 (the thickness of the soft magnetic material layer 505) is 0.5 μm to 5 μm. The spacing between the adjacent sensitive parts 71 is 50 μm to 150 μm. Then, the number of sensitive parts 71 is four in FIG. 2A, but other numbers may be accepted. The number of sensitive parts 71 is, for example, 20.

Note that the size of each sensitive part 71 (the length, the area, the thickness, etc.), the number of sensitive parts 71, the spacing between the sensitive parts 71, or the like may be set in accordance with the magnitude of the magnetic field to be sensed, in other words, to be measured. Note that the number of the sensitive parts 71 may be one.

The connection part 72 is provided between end portions of the adjacent sensitive parts 71 to connect the plural sensitive parts 71 in series. In other words, the connection parts 72 are provided to connect the adjacent sensitive parts 71 windingly (meanderingly). In the sensitive element 1 with four sensitive parts 71 shown in FIG. 2A, there are three connection parts 72. The number of connection parts 72 differs depending on the number of sensitive parts 71. For example, if there are six sensitive parts 71, there will be five connection parts 72. Moreover, if there is one sensitive part 71, no connection part 72 will be provided. Note that the width of the connection part 72 may be set in accordance with the electrical current, etc., to be passed to the sensitive circuit 70. For example, the width of the connection part 72 may be the same as that of the sensitive part 71.

The terminal parts 73 are provided to one end portion and the other end portion of the sensitive parts 71 that are connected in series. In FIG. 2A, a terminal part 73a is provided on the lower side of the page, and a terminal part 73b is provided on an upper side of the page. In the case where the terminal parts 73a and 73b are not distinguished from each other, the terminal parts are referred to as the terminal parts 73. The terminal parts 73 are used to be electrically connected with the circuit through wire bonding, conductive adhesive agents, mechanical contact, or the like, and should have the size necessary for these connections. Note that, in the sensitive element 1 shown in FIG. 2A, since there are four sensitive parts 71, the terminal parts 73a and 73b are provided on the left side of the page. In the case where the number of sensitive parts 71 is an odd number, the two terminal parts 73a and 73b may be divided to be provided into right and left of the page.

As described above, the sensitive circuit 70 is configured so that the sensitive parts 71 are windingly connected in series by the connection parts 72, and the electric currents flow from the terminal parts 73a and 73b provided at both end portions of the connected sensitive parts 71. Therefore, the circuit is referred to as the sensitive circuit 70.

Further, the sensitive element 1 includes yokes 80 each of which is provided to face the end portions of the sensitive parts 71 in the longitudinal direction thereof. Here, there are provided two yokes 80a and 80b, each of which is provided to face each of both end portions of the sensitive part 71 in the longitudinal direction thereof. Note that, in the case where the yokes 80a and 80b are not distinguished from each other, the yokes are referred to as the yokes 80. The yoke 80 guides the magnetic force lines to the end portions of the sensitive part 71 in the longitudinal direction thereof. For this reason, the yoke 80 is constituted by the soft magnetic material through which the magnetic force lines are likely to pass. In the example, the sensitive part 71 and the yoke 80 are constituted by the soft magnetic material layer 505. Note that, in the case where the magnetic force lines sufficiently pass in the longitudinal direction of the sensitive parts 71, it is unnecessary to provide the yokes 80.

Next, with reference to FIG. 2B, the cross-sectional structure of the sensitive element 1 will be described. The sensitive element 1 is configured by arranging an adhesive layer 501, a control layer 502, the hard magnetic material layer 503 (the thin film magnet 60), a dielectric layer 504, and the soft magnetic material layer 505 (the sensitive parts 71 and the yokes 80) in this order on the substrate 50 made of the non-magnetic material.

The substrate 50 is composed of a non-magnetic material; for example, an electrically-insulated oxide substrate, such as glass or sapphire, a semiconductor substrate, such as silicon, or a metal substrate, such as aluminum, stainless steel, or a nickel-phosphorus-plated metal.

The adhesive layer 501 is a layer for improving adhesiveness of the control layer 502 to the substrate 50. As the adhesive layer 501, it is preferable to use an alloy containing Cr or Ni. Examples of the alloy containing Cr or Ni include CrTi, CrTa and NiTa. The thickness of the adhesive layer 501 is, for example, 5 nm to 50 nm. Note that, if there is no problem in adhesiveness of the control layer 502 to the substrate 50, it is unnecessary to provide the adhesive layer 501. Note that, in the present specification, composition ratios of alloys containing Cr or Ni are not shown. The same applies hereinafter.

The control layer 502 controls the magnetic anisotropy of the thin film magnet 60 constituted by the hard magnetic material layer 503 to be likely to express in the in-plane direction of the film. As the control layer 502, it is preferable to use Cr, Mo or W, or an alloy containing thereof (hereinafter, referred to as an alloy containing Cr or the like to constitute the control layer 502). Examples of the alloy containing Cr or the like to constitute the control layer 502 include CrTi, CrMo, CrV and CrW. The thickness of the control layer 502 is, for example, 10 nm to 300 nm.

It is preferable that the hard magnetic material layer 503 constituting the thin film magnet 60 uses an alloy that contains Co as a main component and also contains at least one of Cr and Pt (hereinafter, referred to as a Co alloy constituting the thin film magnet 60). Examples of the Co alloy constituting the thin film magnet 60 include CoCrPt, CoCrTa, CoNiCr and CoCrPtB. Note that Fe may be contained. The thickness of the hard magnetic material layer 503 is, for example, 1 μm to 3 μm.

The alloy containing Cr or the like to constitute the control layer 502 has a bcc (body-centered cubic) structure. Consequently, the hard magnetic material constituting the thin film magnet 60 (the hard magnetic material layer 503) preferably has an hcp (hexagonal close-packed) structure easily causing crystal growth on the control layer 502 composed of the alloy containing Cr or the like having the bcc structure. When crystal growth of the hard magnetic material layer 503 having the hcp structure is caused on the bcc structure, the c-axis of the hcp structure is likely to be oriented in a plane. Therefore, the thin film magnet 60 configured with the hard magnetic material layer 503 is likely to have the magnetic anisotropy in the in-plane direction. Note that the hard magnetic material layer 503 is polycrystalline composed of a set of different crystal orientations, and each crystal has the magnetic anisotropy in the in-plane direction. The magnetic anisotropy is derived from crystal magnetic anisotropy.

Note that, to promote the crystal growth of the alloy containing Cr or the like to constitute the control layer 502 and the Co alloy constituting the thin film magnet 60, the alloys should be heated to 100° C. to 600° C. By the heating, the crystal growth of the alloy containing Cr or the like constituting the control layer 502 is likely to be caused, and thereby crystalline orientation is likely to be provided so that the hard magnetic material layer 503 having the hcp structure includes an axis of easy magnetization in a plane. In other words, the magnetic anisotropy is likely to be imparted in a plane of the hard magnetic material layer 503.

The dielectric layer 504 is configured with a nonmagnetic dielectric material and electrically insulates the thin film magnet 60 and the sensitive circuit 70. Examples of the dielectric material constituting the dielectric layer 504 include oxide, such as SiO₂, Al₂O₃, or TiO₂, or nitride, such as Si₃N₄ or AlN. In addition, the thickness of the dielectric layer 504 is, for example, 0.1 μm to 30 μm.

The sensitive part 71 in the sensitive circuit 70 is provided with uniaxial magnetic anisotropy in a direction crossing the longitudinal direction, for example, an intersecting short direction (the width direction). Note that the direction intersecting the longitudinal direction may have an angle exceeding 45° and not more than 90° with respect to the longitudinal direction.

As the soft magnetic material layer 505 constituting the sensitive part 71, it is preferable to use an amorphous alloy, which is an alloy containing Co as a main component doped with a high melting point metal, such as Nb, Ta or W (hereinafter, referred to as a Co alloy constituting the sensitive part 71). Examples of the Co alloy constituting the sensitive part 71 include CoNbZr, CoFeTa and CoWZr. The thickness of the soft magnetic material constituting the sensitive parts 71 is, for example, 0.2 μm to 2 μm.

The connection parts 72 and the terminal parts 73 in the sensitive circuit 70 are configured with a conductor layer 506 having excellent conductivity. For example, Ag, Cu, Au, or Al can be used, but the material is not particularly limited thereto. Note that the connection part 72 and the terminal part 73 may be configured with different conductor layers. In addition, the connection parts 72 and the terminal parts 73 may be formed integrally with the sensitive parts 71. Thus, it is unnecessary to form the sensitive parts 71, the connection parts 72 and the terminal parts 73 separately.

The adhesive layer 501, the control layer 502, the hard magnetic material layer 503 and the dielectric layer 504 are processed to have a quadrangular planar shape (refer to FIG. 2A). Then, of the exposed side surfaces, in the two facing side surfaces in the x direction, the thin film magnet 60 serves as the north pole ((N) in FIG. 2B) and the south pole ((S) in FIG. 2B). Note that the line connecting the north pole and the south pole of the thin film magnet 60 takes the longitudinal direction (here, the x direction) of the sensitive part 71 in the sensitive circuit 70. Here, to take the longitudinal direction means that an angle formed by the line connecting the north pole with the south pole and the longitudinal direction is less than 45°. Note that the smaller the angle formed by the line connecting the north pole with the south pole and the longitudinal direction, the better.

In the sensitive element 1, the magnetic force lines outputted from the north pole of the thin film magnet 60 once go to the outside of the sensitive element 1. Then, part of the magnetic force lines passes through the sensitive parts 71 via the yoke 80a and goes to the outside again via the yoke 80b. The magnetic force lines that have passed through the sensitive parts 71 return to the south pole of the thin film magnet 60 together with the magnetic force lines that have not passed through the sensitive parts 71. In other words, the thin film magnet 60 applies the magnetic field to the longitudinal direction of the sensitive parts 71.

Note that the north pole and the south pole of the thin film magnet 60 are collectively referred to as both magnetic poles, and when the north pole and the south pole are not distinguished from each other, they are referred to as the magnetic poles.

Note that, as shown in FIG. 2A, the yokes 80 (the yokes 80a and 80b) are configured so that the shape thereof as viewed from the front surface side of the substrate 50 is narrowed as approaching the sensitive circuit 70. This is to increase the magnetic flux density (to gather the magnetic force lines) in the sensitive parts 71. In other words, the magnetic field in the sensitive part 71 is strengthened to further improve the sensitivity. Note that it is unnecessary to narrow the width of the portion of the yoke 80 (the yokes 80a and 80b) facing the sensitive circuit 70.

Here, the spacing between the yoke 80 (the yokes 80a and 80b) and the sensitive circuit 70 should be, for example, 1 μm to 100 μm.

In the above, the sensitive part 71 was assumed to be configured with the single soft magnetic material layer 505; however, it may be possible to configure the soft magnetic material layer 505 with two layers, namely, an upper soft magnetic material layer and a lower soft magnetic material layer, and provide an antiferromagnetically coupled layer between the upper soft magnetic material layer and the lower soft magnetic material layer to antiferromagnetically couples (AFC) the upper soft magnetic material layer and the lower soft magnetic material layer. Examples of materials of such an antiferromagnetically coupled layer include Ru. Provision of the antiferromagnetically coupled layer suppresses demagnetizing fields and improves the sensitivity of the sensitive element 1.

In addition, a conductor layer that reduces the electrical resistance of the sensitive part 71 may be provided between the upper soft magnetic material layer and the lower soft magnetic material layer constituting the sensitive part 71. As the conductor layer, it is preferable to use metal or an alloy having high conductivity, and more preferable to use metal or an alloy that is highly conductive and non-magnetic. Examples of materials of such a conductor layer include metal, such as aluminum, copper, and silver. The thickness of the conductor layer is, for example, 10 nm to 500 nm. Provision of the conductor layer can increase the frequency of the alternating current to be applied to the sensitive circuit 70.

Further, a magnetic domain suppression layer that suppresses occurrence of a closure magnetic domain in the upper soft magnetic material layer and the lower soft magnetic material layer may be provided between the upper soft magnetic material layer and the lower soft magnetic material layer constituting the sensitive part 71. Examples of materials of such a magnetic domain suppression layer include non-magnetic materials, such as Ru and SiO₂, and non-magnetic amorphous metals, such as CrTi, AlTi, CrB, CrTa, and CoW. By suppressing occurrence of the closure magnetic domain in the sensitive parts 71, occurrence of noise due to so-called the Barkhausen effect based on magnetic domain wall displacement is also suppressed.

Note that it may be possible to form the soft magnetic material layer 505 constituting the sensitive part 71 to have multiple layers more than two layers, and provide the antiferromagnetically coupled layer, the conductor layer, or the magnetic domain suppression layer between the multiple layers. In addition, it may also be possible to use two or all of the above-described antiferromagnetically coupled layer, conductor layer and magnetic domain suppression layer in combination.

In the above, the sensitive element 1 was assumed to be provided with the thin film magnet 60 and the yokes 80 in addition to the sensitive circuit 70. The thin film magnet 60 is provided to apply the bias magnetic field Hb, which will be described later, to the sensitive parts 71 in the sensitive circuit 70. In the case where the bias magnetic field Hb is applied from the outside of the sensitive element 1, it is unnecessary for the sensitive element 1 to include the thin film magnet 60. In this case, it is also unnecessary to include the adhesive layer 501, the control layer 502, the hard magnetic material layer 503, and the dielectric layer 504, which are provided for the thin film magnet 60. In other words, the sensitive element 1 should be configured with the sensitive circuit 70 provided on the substrate 50. In this case, the yokes 80 may or may not be provided.

Examples of methods for applying the bias magnetic field Hb from the outside of the sensitive element 1 include methods using the permanent magnet or bias coil. It may be possible only to place them close to the sensitive element 1; however, it is preferable to use a magnetic path configured with a soft magnetic material, such as a ferrite core, to suppress the leakage of the bias magnetic field due to the permanent magnet or the bias coil to the outside.

In the case where the sensitive circuit 70 is provided on the substrate 50, if the substrate 50 is configured with a semiconductor substrate, such as silicon, or a metal substrate, such as aluminum, stainless steel, or a nickel-phosphorus-plated metal, the substrate 50 has high conductivity. In such a case, an insulating material layer to electrically insulate the substrate 50 from the sensitive circuit 70 should be provided on the surface of the substrate 50 on which the sensitive circuit 70 is provided. Examples of the insulating material constituting the insulating material layer include, similar to the dielectric material constituting the dielectric layer 504, oxide such as SiO₂, Al₂O₃, or TiO₂, or nitride such as Si₃N₄ or AlN.

The sensitive element 1 in the present specification may be, in addition to the one that includes the thin film magnet 60 as shown in FIGS. 2A and 2B, the one in which the sensitive circuit 70 is provided on the substrate 50. Further, the sensitive element 1 may include only the sensitive circuit 70.

### (Action of Sensitive Element 1)

Subsequently, the action of the sensitive element 1 will be described.

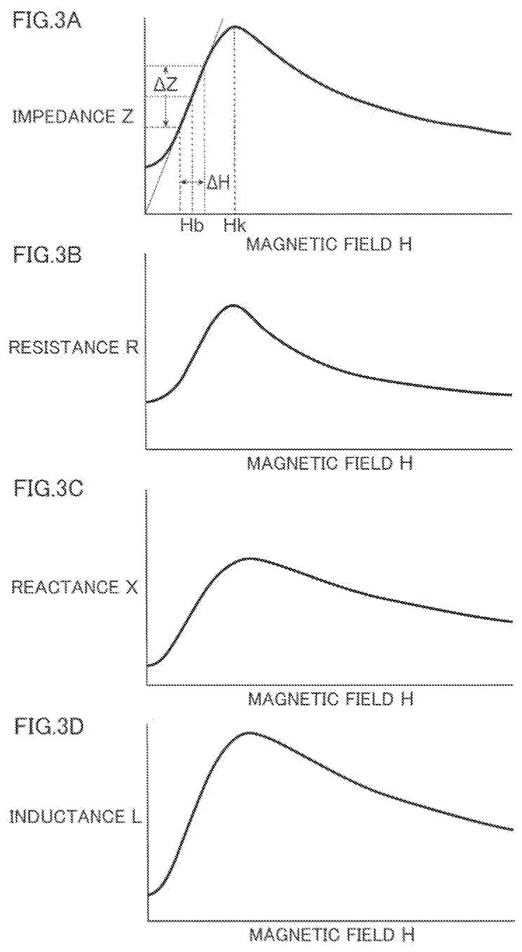

FIG. 3A illustrates a relation between the magnetic field H applied in the longitudinal direction of the sensitive part 71 of the sensitive element 1 (the x direction in FIG. 2A) and an impedance Z of the sensitive element 1. In FIG. 3A, the horizontal axis indicates the magnetic field H, and the vertical axis indicates the impedance Z. Note that the impedance Z is measured by passing the alternating current between the terminal parts 73a and 73b of the sensitive circuit 70 shown in FIG. 2A. Consequently, though the impedance Z is the impedance of the sensitive circuit 70, it is referred to as the impedance Z of the sensitive element 1.

As shown in FIG. 3A, the impedance Z of the sensitive element 1 is increased as the magnetic field H applied in the longitudinal direction of the sensitive parts 71 is increased. Then, within the range in which the magnetic field H to be applied is smaller than the anisotropic magnetic field Hk of the sensitive parts 71, by use of a portion where the amount of change ΔZ in the impedance Z with respect to the amount of change ΔH in the magnetic field H is steep (ΔZ/ΔH is large), it is possible to extract extremely weak change in the magnetic field H as the amount of change ΔZ in the impedance Z. In FIG. 3A, the center of the magnetic field H where ΔZ/ΔH is large is shown as the magnetic field Hb. In other words, it is possible to measure the amount of change (ΔH) in the magnetic field H in the vicinity to the magnetic field Hb (the range indicated by arrows in FIG. 3A) with high accuracy. Here, the portion where the amount of change ΔZ in the impedance Z is the steepest (ΔZ/ΔH is the largest), that is, the amount of change Zmax of the impedance per unit magnetic field in the magnetic field Hb divided by the impedance Z in the magnetic field Hb (referred to as the impedance Zb) (Zmax/Zb) is the sensitivity. As the sensitivity is higher, the magnetic impedance effect becomes larger and the magnetic field or the change in the magnetic field can be easily measured. Then, as the frequency of the alternating current applied to the sensitive circuit 70 is higher, the sensitivity becomes higher. The magnetic field Hb is referred to as a bias magnetic field in some cases. Hereinafter, the magnetic field Hb is referred to as the bias magnetic field Hb.

The sensitive element 1 is brought into the state in which the bias magnetic field Hb is applied in advance by the thin film magnet 60 shown in FIG. 2B.

By looking at the sensitive element 1 as an impedance element, the above description can be given; however, the sensitive element 1 can be represented by an equivalent circuit connecting the resistance and the inductance in series, and is combined with the capacitive element to form an RLC series circuit; therefore, in considering the characteristics thereof, it is necessary to consider the characteristics of the resistance R, the reactance X, and the inductance L.

FIG. 3B illustrates a relation between the magnetic field H applied in the longitudinal direction of the sensitive part 71 of the sensitive element 1 (the x direction in FIG. 2A) and the resistance R of the sensitive element 1. In FIG. 3B, the horizontal axis indicates the magnetic field H, and the vertical axis indicates the resistance R.

FIG. 3C illustrates a relation between the magnetic field H applied in the longitudinal direction of the sensitive part 71 of the sensitive element 1 (the x direction in FIG. 2A) and the reactance X of the sensitive element 1. In FIG. 3C, the horizontal axis indicates the magnetic field H, and the vertical axis indicates the reactance X.

FIG. 3D illustrates a relation between the magnetic field H applied in the longitudinal direction of the sensitive part 71 of the sensitive element 1 (the x direction in FIG. 2A) and the inductance L of the sensitive element 1. In FIG. 3D, the horizontal axis indicates the magnetic field H, and the vertical axis indicates the inductance L.

Here, the impedance Z, the resistance R, the reactance X, and the inductance L are in the following relation, where ω is the angular frequency (rad/sec), and f is the frequency (Hz):

Z=R+jX=R+jωL ω=2πf

In the sensitive element shown in FIGS. 3A to 3D, similar to the impedance Z, with any of the resistance R, the reactance X, and the inductance L, each value increases as the magnetic field H increases near the magnetic field Hb, and the change is the largest.

### (Magnetic Sensor 110)

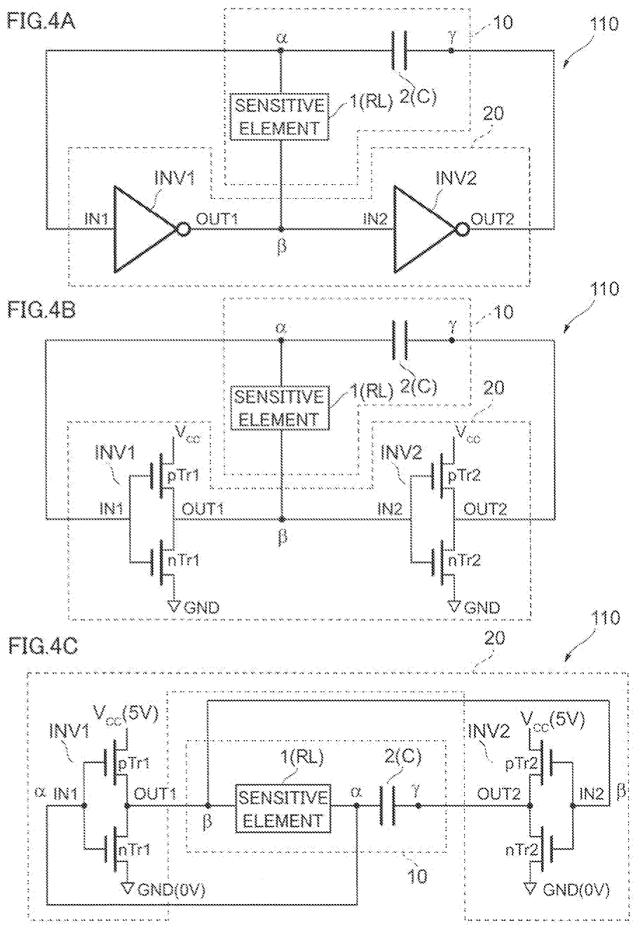

FIGS. 4A to 4C illustrate a magnetic sensor 110, to which the first exemplary embodiment is applied. FIG. 4A shows an equivalent circuit indicated by logical symbols, FIG. 4B shows an equivalent circuit indicated by the transistors, and FIG. 4C is an equivalent circuit that is the deformation of the circuit shown in FIG. 4B.

As shown in FIG. 4A, the magnetic sensor 110 includes the frequency setting part 10 and the potential supply part 20 provided with two inverters, INV1 and INV2. The description will be given assuming that, here, the frequency setting part 10 includes the sensitive element 1 and the capacitive element 2 connected in series, as described above. Hereinafter, the sensitive element 1 is represented as the sensitive element 1(R), the sensitive element 1(RL), or the capacitive element 2(C) in some cases. The sensitive element 1(R) means the case where the equivalent circuit of the sensitive element includes only the resistance R, and the sensitive element 1(RL) means the case where the equivalent circuit of the sensitive element is the series circuit including the resistance R and the inductance L. In addition, in FIG. 4A, the sensitive element 1 is denoted as 1(RL), and the capacitive element 2 is denoted as 2(C). The same applies hereinafter. Note that the inverter INV1 is an example of a first inverter, and the inverter INV2 is an example of a second inverter.

The inverter INV1 includes an input terminal IN1 and an output terminal OUT1. The inverter INV2 includes an input terminal IN2 and an output terminal OUT2. In the following description, the input terminal is referred to as input, and the output terminal is referred to as output.

The inverters INV1 and INV2 are elements that invert the logic level of the input signal to generate the output signal. In other words, when the logic level “H” is inputted to the input IN1, the inverter INV1 outputs the inverted logic level “L” from the output OUT1, and when the logic level “L” is inputted to the input IN1, the inverter INV1 outputs the inverted logic level “H” from the output OUT1. Note that, in the case where the inverters INV1 and INV2 are not distinguished from each other, the inverters are referred to as inverters INV. Moreover, inversion of the output from the inverter INV is sometimes referred to as switching.

Here, it is assumed that the connection point where one of the terminal parts 73 (for example, the terminal part 73a (refer to FIG. 2A)) of the sensitive element 1 (RL) and one of the terminals of the capacitive element 2(C) are connected is the point α, the other terminal part 73 (for example, the terminal part 73b (refer to FIG. 2A)) of the sensitive element 1(RL) is the point β, and the other terminal of the capacitive element 2(C) is the point γ. Note that the terminals include the pad-like ones provided to connect the wiring shown in FIG. 2A, as well as the wiring pattern provided on circuit boards to be loaded with the capacitive element 2.

The inverters INV1 and INV2 are connected in series. In other words, the output OUT1 of the inverter INV1 is connected to the input IN2 of the inverter INV2. Then, the point β of the frequency setting part 10 is connected to the connection point between the output OUT1 of the inverter INV1 and the input IN2 of the inverter INV2. That is, the point β, the output OUT1, and the input IN2 have the same potential. Consequently, these are sometimes referred to as the point β (output OUT1), the point β (input IN2), or the like to indicate to have the same potential. Then, the point α of the frequency setting part 10 is connected to the input IN1 of the inverter INV1, and the point γ of the frequency setting part 10 is connected to the output OUT2 of the inverter INV2. In other words, the point α and the input IN1 of the inverter INV1 have the same potential, and the point γ and the output OUT2 of the inverter INV2 have the same potential. Consequently, these are sometimes referred to as the point α (input IN1), the point γ (output OUT2), to indicate to have the same potential.

In FIG. 4B, the inverters INV1 and INV2 are shown as the inverters in a CMOS configuration as an example. Here, the inverter INV1 has a p-channel transistor pTr1 and an n-channel transistor nTr1. Similarly, the inverter INV2 has a p-channel transistor pTr2 and an n-channel transistor nTr2. Then, in the inverter INV1, the gate of the transistor pTr1 and the gate of the transistor nTr1 are connected to form the input IN1. In addition, the drain of the transistor pTr1 and the drain of the transistor nTr1 are connected to form the output OUT1. Similarly, in the inverter INV2, the gate of the transistor pTr2 and the gate of the transistor nTr2 are connected to form the input IN2. In addition, the drain of the transistor pTr2 and the drain of the transistor nTr2 are connected to form the output OUT2. Then, the ground potential GND, which is the reference potential, is supplied to the source of the transistor nTr1 and the source of the transistor nTr2, and the power supply potential V_{CC} is supplied to the source of the transistor pTr1 and the source of the transistor pTr2. Here, regarding the voltage level of the outputs OUT1 and OUT2 of INV1 and INV2, respectively, the ground potential GND is at the logic level “L,” and the power supply potential V_{CC} is at the logic level “H.”

The operation of the inverters INV1 and INV2 will be described with reference to the inverter INV1.

When the input IN1 of the inverter INV1 is at the ground potential GND (the logic level “L”), the transistor pTr1 is turned on, the transistor nTr1 is turned off, and the output OUT1 is at the power supply potential V_{CC} (the logic level “H”). Conversely, when the input IN1 of the inverter INV1 is at the power supply potential V_{CC} (the logic level “H”), the transistor pTr1 is turned off, the transistor nTr1 is turned on, and the output OUT1 is at the ground potential GND (the logic level “L”). Then, when the input IN1 transitions from the ground potential GND side to the power supply potential V_{CC} side beyond the threshold voltage Vth, when the input IN1 reaches the threshold voltage Vth, the output OUT1 inverts from the power supply potential V_{CC} (the logic level “H”) to the ground potential GND (the logic level “L”). Conversely, when the input IN1 transitions from the power potential V_{CC} side to the ground potential GND side below the threshold voltage Vth, when the input IN1 reaches the threshold voltage Vth, the output OUT1 inverts from the ground potential GND (the logic level “L”) to the power supply potential V_{CC} (the logic level “H”).

FIG. 4C deforms the equivalent circuit in FIG. 4B to show the frequency setting part 10 at the center of the figure. The connection relationship between the elements is the same in FIGS. 4B and 4C. As can be seen from FIG. 4C, the inverters INV1 and INV2 constitute a full bridge.

### (Operation of Magnetic Sensor 110)

First, description will be given of the case where the frequency setting part is an RC series circuit.

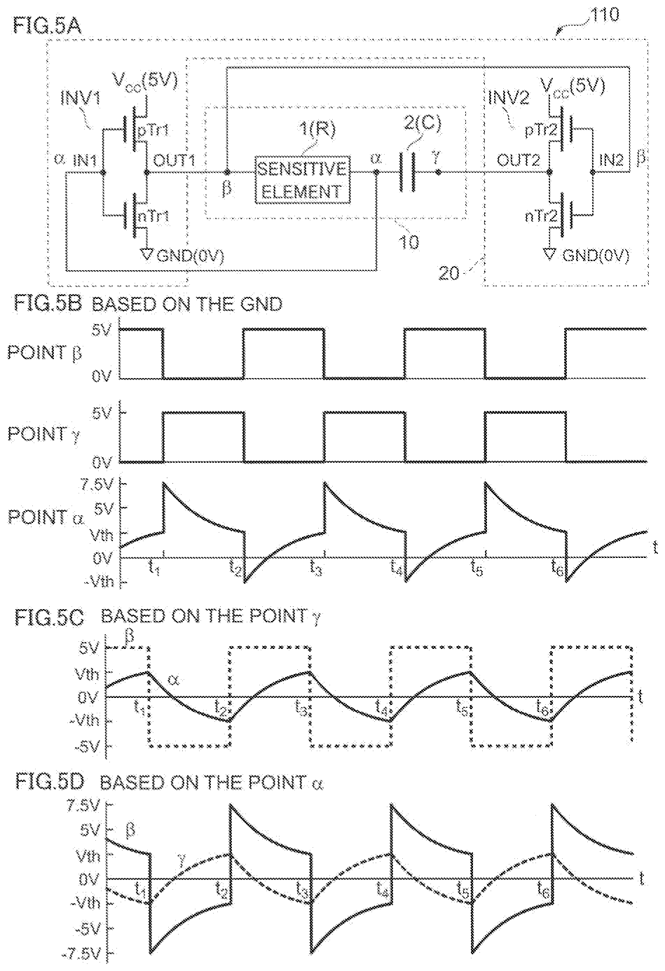

FIGS. 5B to 5D show timing charts illustrating operations of the magnetic sensor 110, to which the first exemplary embodiment is applied, in the case where the equivalent circuit of the sensitive element 1 is configured with only the resistance R, for the sake of simplifying. For simplifying, the propagation delay time of the inverter is not taken into consideration, and the description will be given on the assumption that the inversion of the output occurs at once. FIG. 5A shows the equivalent circuit of the magnetic sensor 110 shown in FIG. 4C, FIG. 5B shows a timing chart for each potential at the points α, β and γ based on the ground potential GND, FIG. 4C shows a timing chart for each potential at the points α and β based on the potential at the point γ, and FIG. 5D shows a timing chart for each potential at the points β and γ based on the potential at the point α. Note that the potential of the point β based on the potential of the point α shown in FIG. 5D corresponds to the voltage applied to the sensitive element 1(R). Further, the potential is a voltage with reference to the ground potential GND, and the voltage is a potential difference between two points, but the potential and the voltage are not distinguished from each other in some cases.

In FIGS. 5B to 5D, the horizontal axis indicates time, and the vertical axis indicates voltage. Then, times t₁ to t₆ are arranged on the horizontal axis, and the time is assumed to pass in this order. Here, it is assumed that the ground potential GND is “0V, ” and the power supply potential V_{CC} is “5V.” In this case, the threshold voltage Vth is assumed to be “2.5V,” which is between the ground potential GND (0V) and the power supply potential V_{CC} (5V).

In FIG. 5B, the potentials at the points β, γ, and α based on the ground potential GND will be described with reference to FIG. 5A.

At the time t₁, when the point α (the input IN1) reaches the threshold voltage Vth (2.5V) from the 0V side, the inverter INV1 inverts and the point β (the output OUT1) is shifted from 5V to 0V. This causes the point β of the inverter INV2 (the input IN2) to shift from 5V to 0V, and thereby the inverter INV2 inverts and the point γ (the output OUT2) is shifted from 0V to 5V. Just before the inverter INV1 is inverted, the point α is the threshold voltage Vth (2.5V), and the point γ is 0V. Since the voltage applied to the capacitive element 2(C) is the potential difference between the points α and γ, the voltage applied to the capacitive element 2(C) is 2.5 V. When the inverter output is inverted instantaneously, the capacitive element 2(C) is not charged or discharged instantaneously, and to maintain the potential difference of 2.5 V, when the point γ (the output OUT2) is shifted from 0V to 5V due to the inversion of the inverter INV2, the point α is shifted to 7.5V, which is the result of addition of 5V to the threshold voltage Vth (2.5V).

Thereafter, from the point α of 7.5V to the point β of 0V, the electric charges accumulated in the capacitive element 2(C) flow through the sensitive element 1(R). Consequently, the potential at the point α gradually decreases. The transient response of the decrease is determined by the time constant τ, which is determined by the resistance R of the sensitive element 1 and the capacitance C of the capacitive element 2. Here, the time constant τ is given by

τ=RC.

Since the voltage at time t₁ is V_{CC}+threshold voltage Vth, the potential V₍ₜ₎ at the point α after t seconds have elapsed from the time t₁ is

V₍ₜ₎=(V_{CC}+Vth)e^{-t/τ}, and the potential gradually decreases from 7.5V.

Then, at the time t₂, when the point α (the input IN1) decreases from 7.5V to reach the threshold voltage Vth, the inverter INV1 inverts and the point β (the output OUT1) is shifted from 0V to 5V. This causes the point β of the inverter INV2 (the input IN2) to shift from 0V to 5V, and thereby the inverter INV2 inverts and the point γ (the output OUT2) is shifted from 5V to 0V. Just before the inverter INV1 is inverted, the point α was the threshold voltage Vth (2.5V). Accordingly, when the inverter INV2 is inverted and the point γ (the output OUT2) is shifted from 5V to 0V, the point α is shifted to −2.5V, which is the result of subtraction of 5V from the threshold voltage Vth (2.5V). The transient response of the increase is also determined by the time constant τ.

Thereafter, by the current flowing from the point β of 5V to the point α of −2.5V through the sensitive element 1(R) to accumulate electric charges in the capacitive element 2(C), the potential of the point α gradually increases.

Then, at the time t₃, when the point α (the input IN1) increases from −2.5V to reach the threshold voltage Vth (2.5V), the inverter INV1 inverts and the point β (the output OUT1) is shifted from 5V to 0V. This causes the point β of the inverter INV2 (the input IN2) to shift from 5V to 0V, and thereby the inverter INV2 inverts and the point γ (the output OUT2) is shifted from 0V to 5V. Just before the inverter INV1 is inverted, the point α was the threshold voltage Vth (2.5V). Accordingly, when the inverter INV2 is inverted and the point γ (the output OUT2) is shifted to 5V, the point α is shifted to 7.5V, which is the result of addition of 5V to the threshold voltage Vth (2.5V). In other words, the time t₃ is the same as the time t₁.

Thereafter, the potential change from the time t₁ to the time t₃ is repeated.

In FIG. 5C, the voltages at the points α and β based on the point γ will be described with reference to FIG. 5A. Note that, in FIG. 5C, the voltage at the point α is shown by a solid line, and the voltage at the point β is shown by a broken line. The voltages at the points α and β are obtained from the differences between the potentials at the points α and β and the potential at the point γ, respectively, in FIG. 5B.

The voltage at the point α based on of the point γ means the voltage applied to the capacitive element 2(C). In addition, the voltage at the point β based on the point γ means the voltage applied to the frequency setting part 10.

The potential at the point β is shifted from 5V to −5V at the time t₁, and shifted from −5V to 5V at the time t₂. Then, at the time t₃, the shift from 5V to −5V occurs similar to the time t₁. In other words, the potential difference between the points β and γ point is always +/−5V. Since the inverters INV1 and INV2 constitute a full bridge, the voltage change of 10 V occurs at the frequency setting part 10 when the output of the inverter is inverted.

On the other hand, the point α is the threshold voltage Vth (2.5V) at the time t₁, shifted to the voltage deviated by the threshold voltage Vth toward the negative side (−2.5V) at the time t₂, and returns to the threshold voltage Vth (2.5V) at the time t₃.

Consequently, the capacitive element 2(C) is charged and discharged at the voltage of +/−Vth.

Then, at both points α and β, the voltage change from the time t₁ to the time t₃ is repeated.

In FIG. 5D, the voltages at the points β and γ based on the point α will be described with reference to FIG. 5A. Note that, in FIG. 5D, the voltage at the point β is shown by a solid line, and the voltage at the point γ is shown by a broken line. The voltages at the points β and γ are obtained from the differences between the potentials at the points β and γ and the potential at the point α, respectively, in FIG. 5B. Note that, as can be seen from FIG. 5A, the voltage at the point β is the voltage applied between the points α and β point, namely, to the sensitive element 1(R).

Since the voltage at the point γ is the potential difference between the points α and γ, the voltage at the point α shown in FIG. 5C is reversed between positive and negative.

At the time t₁, the voltage at the point β is shifted from the threshold voltage Vth (2.5V) to −7.5V, which is the result of addition of the threshold voltage Vth (2.5V) to the power supply potential V_{CC} (5V) on the negative side. Then, the voltage gradually increases from the time t₁ to the time t₂, and at the time t₂, the voltage reaches the threshold voltage Vth on the negative side (−2.5V). At the time t₂, the voltage is shifted from −2.5V to 7.5V, which is the result of addition of the threshold voltage Vth (2.5V) to the power supply potential V_{CC} (5V). Then, the voltage gradually decreases from the time t₂ to the time t₃, and at the time t₃, the voltage reaches the threshold voltage Vth (2.5V). At the time t₃, the voltage is shifted from 2.5V to −7.5V, which is the result of addition of the threshold voltage Vth (2.5V) to the power supply potential V_{CC} (5V) on the negative side.

Then, at the point β, the voltage change from the time t₁ to the time t₃ is repeated.

As described above, an AC voltage with a period from the time t₁ to the time t₃ is applied to the sensitive element 1(R), and an alternating current flows therethrough. The frequency of the alternating current is determined by the resistance R of the sensitive element 1 and the capacitance C of the capacitive element 2. Then, the sensitive element part 11 including the sensitive element 1 and the capacitive element part 12 including the capacitive element 2 are collectively referred to as the frequency setting part 10. The resistance R of the sensitive element 1 changes depending on the magnetic field H as shown in FIG. 3B. Consequently, by measuring the frequency or frequency change of the alternating current flowing through the magnetic sensor 110, the magnetic field or the change in the magnetic field sensed by the sensitive element 1 can be measured. In other words, a full bridge constituted by the inverters INV1 and INV2 is configured as an oscillation circuit that generates the alternating current.

Next, description will be given of the case where the frequency setting part is an RLC series circuit.

Here, the sensitive element 1(RL) is a series circuit with the resistance R and the inductance L as the equivalent circuit of the sensitive element, and is further connected in series with the capacitive element 2(C) to form an RLC series circuit. Description will be given of the operation of the magnetic sensor 110, to which the first exemplary embodiment is applied, in this case.

The basic operation is similar to the case shown in FIG. 5, where the frequency setting part is the RC series circuit; however, when the inductance L is added, the attenuation by τ=RC as described above is further delayed by oscillation by ω=1/√LC. Here, ω is the resonance angular frequency (rad/second) of an LC circuit. In the case where C is constant, since ω decreases as L increases, the oscillation period increases. Accordingly, since the time taken to attenuate the voltage to the threshold voltage Vth is increased, the frequency of the alternating current flowing to the magnetic sensor 110 is reduced.

Thus, the frequency of the alternating current is determined by the resistance R, the inductance L of the sensitive element 1, and the capacitance C of the capacitive element 2. Then, the resistance R and the inductance L of the sensitive element 1 change depending on the magnetic field H as shown in FIGS. 3B and 3D. Consequently, by measuring the frequency or frequency change of the alternating current flowing through the magnetic sensor 110, the magnetic field or the change in the magnetic field sensed by the sensitive element 1 can be measured.

Note that the description was given of the magnetic sensor 110 in the first exemplary embodiment as the relaxation oscillation circuit by the RLC series circuit; however, various types of oscillation circuits can be used for the magnetic sensor 110 as long as the oscillation circuit has frequency change caused by the change in the characteristics of the sensitive element 1 due to the external magnetic field.

For example, an LC resonance circuit is configured with the inductance of the sensitive element and the capacitive element, to thereby make it possible to use an LC oscillation circuit utilizing the change in the LC resonance frequency due to the change in the inductance of the sensitive element caused by the external magnetic field. Examples of the LC oscillation circuit include a Colpitts oscillation circuit. If the sensitive element 1(RL) is used instead of the inductance L of the LC oscillation circuit, the frequency of the oscillation circuit changes because the inductance L of the sensitive element 1(RL) changes due to the change in the external magnetic field.

### (Configuration of Frequency Measurement Part 30)

As described above, the frequency measurement part 30 includes the obtaining part 31 and the frequency determination part 32.

The obtaining part 31 obtains the output signal from the magnetic sensor 110. The output signal can be said to be an alternating current oscillating at a frequency determined in accordance with the strength of the magnetic field by use of the magnetic sensor 110.

Note that the obtaining part 31 not only utilizes the output signal from the magnetic sensor 110 as it is, but also performs predetermined processing thereon. For example, the obtaining part 31 shapes the output signal from the magnetic sensor 110 to form a square wave. Then, the square wave is used as an output signal. In addition, it is preferable that the obtaining part 31 integrates and averages the output signal as the predetermined processing. This reduces phase noise and improves the accuracy of the frequency measurement of the output signal.

Note that, if the output signal of the magnetic sensor 110 has less noise and the frequency is stable, the output of the magnetic sensor 110 can be outputted directly to the frequency determination part 32 without the obtaining part 31.

The frequency determination part 32 determines the frequency of the output signal. In the exemplary embodiment, the frequency determination part 32 utilizes interference between the output signal and a reference signal having a reference frequency, which is the frequency used as a reference, to determine the frequency of the output signal.

The obtaining part 31 and the frequency determination part 32 are achieved by cooperation of the hardware resources and software. Examples of the hardware resources include computer devices, such as logic ICs to be described later, mixers, D-flip-flop circuits, and personal computers (PCs). In addition, regarding the software, a not-shown CPU in a computer device loads a program as the software into a main memory (not shown) and executes thereof to perform processing of various types of signals.

### (Configuration of Frequency Determination Part 32)

Next, a configuration of the frequency determination part 32 will be described in detail.

Conventionally, the amplitude of the output signal was measured, and the strength of the magnetic field was calculated based on the measured amplitude. This could be said that the voltage of the output signal was measured, and the strength of the magnetic field was calculated based on the measured voltage. In this case, it is difficult to detect the minute changes in voltage, and the accuracy of the strength of the magnetic field calculated from the detected minute changes in voltage is likely to decrease. For example, the difference of 1 ppm corresponds to 1 μV for a voltage of 1V, which is the difference buried in noise. There is also a method to amplify the voltage and increase the difference, but the noise created prior to amplification is also amplified, and therefore, it is difficult to detect a change in voltage.

Therefore, in the exemplary embodiment, the frequency of the output signal is measured to solve the problem. This can also be said to be a time measurement of the output signal. As compared to measurement of the voltage, it is easier to measure minute changes in frequency, and the accuracy of the strength of the magnetic field to be calculated from the measured minute changes in frequency is likely to be improved. For example, the difference of 1 ppm corresponds to the accuracy of 2.6 seconds per month; accordingly, the difference can be detected by the time measurement.

However, if the frequency of the output signal becomes high frequency, it is sometimes difficult to simply detect the changes in frequency. In such a case, it is necessary to increase the frequency resolution to detect the minute changes in frequency. In other words, it is necessary to increase the temporal resolution, and high-speed sampling is required. On the other hand, if the frequency of an output signal becomes 100 MHz or more, it is difficult to perform high-speed sampling that measures one period at high resolution. For example, in the case where the frequency of the output signal is 200 MHz, one period is 5 n seconds. At this time, 1 ppm is 5 f seconds, which is too short and difficult to measure.

On the other hand, if the frequency of the output signal is too low, there is a problem that the temporal resolution of the magnetic field strength, which varies in time, is reduced. For example, with a signal frequency of 1 Hz, the waveform of the magnetic field strength that varies at a period of 1 Hz cannot be represented. In the case where the magnetic field strength that varies at a period of 1 Hz is expressed by 100 points/period, the temporal resolution of 10 m seconds is required. To achieve this, it is necessary to accurately read the signal frequency within 10 m seconds; however, if the signal frequency is 1 Hz, it is required to read the signal frequency from a waveform of 1/100 of one period, and therefore, it is difficult to measure accurately. Consequently, it is necessary to convert the signal frequency into an adequate frequency, with which the minute changes in frequency can be detected and the temporal resolution of the magnetic field strength variation can be sufficiently high.

To solve this, for example, if the frequency of the output signal is divided, the frequency can be converted into a lower frequency, and the frequency resolution at a predetermined sampling rate is improved. However, this method also reduces the amount of change in frequency; therefore, the rate of change in frequency is not improved.

For example, in the case where the difference of 1 ppm in the frequency of 200 MHz is detected, if the frequency is divided to 1/1,000,000, the time variation of 1 ppm becomes 5 n seconds, which can be measured. However, since the frequency of the output signal is also converted to 1/1,000,000, the output signal of 200 MHz output signal is converted into 2 Hz, and thereby the temporal resolution in the magnetic field signal detection is reduced. For this reason, a method that increases the rate of change in the frequency by reducing the frequency without changing the amount of change in the frequency as much as possible is required.

Accordingly, in the exemplary embodiment, in measuring the frequency of the output signal, interference between the output signal and a reference signal having a reference frequency, which is the frequency used as a reference, is utilized to perform the time measurement, to thereby solve the problem, as described below.

### First Exemplary Embodiment

To begin with, a first exemplary embodiment will be described. In the first exemplary embodiment, the frequency determination part 32 determines the frequency of the output signal on the basis of the waveform obtained based on the phase difference between the output signal and the reference signal as a result of interference between the output signal and the reference signal.

Here, description will be given of the case in which the logical operation causes the output signal and the reference signal to interfere with each other.

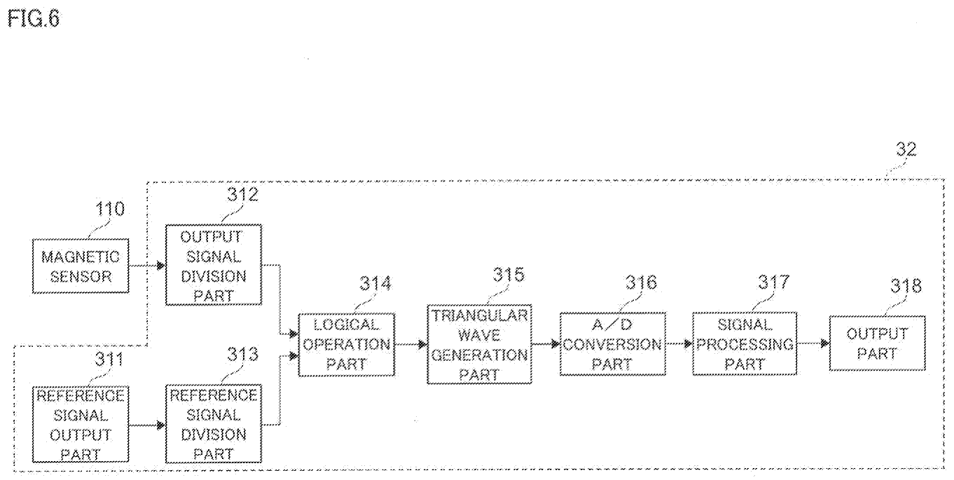

FIG. 6 shows a conceptual diagram of a circuit configuration that uses logical operations to cause the output signal and the reference signal interfere with each other.

The circuit configuration shown in the figure includes: a reference signal output part 311 that outputs the reference signal; an output signal division part 312 that divides the output signal emitted by the magnetic sensor 110; a reference signal division part 313 that divides the reference signal outputted from the reference signal output part 311; a logical operation part 314 that performs logical operations; a triangular wave generation part 315 that generates triangular waves; an A/D conversion part 316 that performs A/D conversion; a signal processing part 317 that obtains the frequency of the triangular wave; and an output part 318 that outputs the frequency.

The reference signal output part 311 outputs a reference signal at a predetermined frequency. Here, the output signal from the magnetic sensor 110 has been converted into a square wave in advance by the obtaining part 31. Then, the reference signal output part 311 outputs a square wave at a predetermined frequency as the reference signal. It is preferable that the reference signal output part 311 has a frequency that is relatively close to the frequency of the output signal. Therefore, the frequency of the reference signal is not necessarily the one, but a reference signal with plural frequencies is prepared. The reference signal with plural frequencies can be generated by dividing the reference signal in the reference signal division part 313.

The output signal division part 312 divides the output signal as needed. Although the phase noise is reduced by being integrated and averaged by dividing, the temporal resolution of magnetic field detection is also reduced; accordingly, it is desirable to keep the division ratio to the minimum capable of reducing the phase noise that can be accurately processed by the logical operation part 314. In addition, the reference signal division part 313 divides the reference signal as needed. The output signal division part 312 and the reference signal division part 313 can be configured with a binary counter or a prescaler. In addition, a phase locked loop (PLL), such as a clock generator, can provide a configuration that integrates the reference signal output part 311 and the reference signal division part 313.

The logical operation part 314 performs a logical operation of the output signal divided by the output signal division part 312 and the reference signal divided by the reference signal division part 313. These signals are square waves, and the logical operation is performed assuming 1 when the pulse is ON and assuming 0 when the pulse is OFF. The logical operation is not particularly limited, and any of XOR (exclusive OR), NOR (negative OR), NAND (not AND), OR (logical OR), and AND (logical AND) can be used. The logical operation part 314 can be configured, for example, by the logic IC. In addition, the phase frequency comparator of the PLL can also be used.

The triangular wave generation part 315 generates a triangle wave based on the waveform outputted by the logical operation part 314.

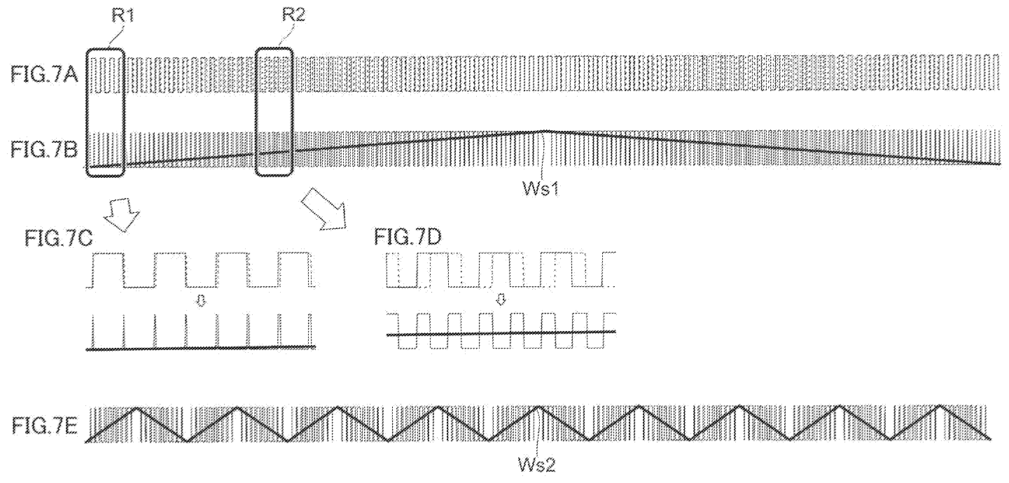

FIGS. 7A to 7E show operations of the logical operation part 314 and the triangular wave generation part 315.

Of these, FIG. 7A shows a case in which square waves of the output signal and the reference signal are superimposed. Here, the output signal is shown by a dotted line, and the reference signal is shown by a solid line.

Then, FIG. 7B shows a waveform outputted as a result of the logical operation of the output signal and the reference signal by the logical operation part 314. Here, the logical operation part 314 performs the logical operation by XOR (exclusive OR).

FIG. 7C is an enlarged view of the region R1 in FIGS. 7A and 7B, and FIG. 7D is an enlarged view of the region R2 in FIGS. 7A and 7B.

As shown in the upper side of FIG. 7C, in the region R1, the waveform of the output signal and the waveform of the reference signal are almost identical. This can be said that the phases thereof are almost identical. At this time, when the logical operation part 314 performs a logical operation by XOR (exclusive OR), the waveform of ON can be obtained in the case where one of the output signal and the reference signal is ON and the other one is OFF. As a result, as shown in the lower side of FIG. 7C, the square wave can be obtained, in which the ON time is short.

In addition, as shown in the upper side of FIG. 7D, in the region R2, the waveforms of the output signal and the waveform of the reference signal are shifted from each other. This can be said that the phases thereof are shifted from each other. At this time, when the logical operation part 314 performs a logical operation by XOR (exclusive OR), as described above, the waveform of ON can be obtained in the case where one of the output signal and the reference signal is ON and the other one is OFF. As a result, as shown in the lower side of FIG. 7D, the square wave can be obtained, in which the ON time is relatively long.

In other words, the waveform generated by the XOR (exclusive OR) in the logical operation part 314 is a square wave with a shorter pulse width as the phases of the output signal and the reference signal match better, and is a square wave with a longer pulse width as the phases of the output signal and the reference signal are shifted more from each other. That is, pulse width modulation (PWM) output is obtained.

Then, the triangular wave generation part 315 averages the waveform of the square waves generated as shown in FIGS. 7C and 7D with respect to time. It is also possible to consider that the triangular wave generation part 315 is a low-pass filter (LPF). That is, the PWM output is converted into a triangular wave. As a result, the waveform shown by thick lines in FIGS. 7C and 7D can be obtained. In other words, in FIG. 7C, since the square wave has the short pulse width, the voltage level is low if the waveform is averaged with respect to time. On the other hand, in FIG. 7D, since the square wave has the long pulse width, the voltage level is high if the waveform is averaged with respect to time.

Then, in the case where this is applied to the longer time as shown in FIG. 7B, the triangular wave Ws1 shown by the thick line in FIG. 7B is obtained.

The frequency of the triangular wave Ws1 is determined by the amount of shift between the frequency of the output signal and the reference frequency. In other words, the more the frequency of the output signal and the frequency of the reference signal match, the longer the period is. That is, the frequency of the triangular wave Ws1 is further reduced. In contrast thereto, as the frequency of the output signal and the frequency of the reference signal are shifted further and differ from each other, the period becomes shorter. That is, the frequency of the triangular wave Ws1 is more increased.

The frequency of the triangular wave Ws1 is represented by an absolute value of the difference between the frequency of the output signal and the frequency of the reference signal.

Consequently, based on the frequency of the triangular wave Ws1, the difference between the frequency of the output from the output signal division part 312 that was inputted to the logical operation part 314 and the frequency of the output from the reference signal division part 313 can be obtained, and further, the difference between the frequency of the output signal and the frequency of the reference signal can be obtained from the division ratio of the output signal division part 312 and the reference signal division part 313. Since the frequency of the reference signal is determined in advance, the frequency of the output signal can be obtained from the difference. On the other hand, since the frequency of the triangular wave Ws1 is represented by an absolute value of the difference between the frequency of the output signal and the frequency of the reference signal, the amount of change in the frequency of the output signal that has been minutely changed by the external magnetic field is maintained as it is. In the triangular wave Ws1, the frequency change rate increases because the frequency decreases while the amount of change in the frequency of the output signal is maintained. Accordingly, it becomes possible to measure the minute frequency difference caused by the external magnetic field.

Note that FIG. 7E shows the triangular wave Ws2 generated in the case where the amount of shift between the frequency of the output signal and the frequency of the reference signal is larger than in FIG. 7B. The period of the triangular wave Ws2 is shorter than that of the triangular wave Ws1.

The frequencies of the triangular waves Ws1 and Ws2 are lower than the frequency of the output signal. Accordingly, the frequencies of the triangular waves Ws1 and Ws2 can be detected at a lower sampling rate than to directly detect the frequency of the output signal. In other words, by detecting the frequencies of the triangular waves Ws1 and Ws2, the frequency of the output signal can be obtained without conducting the high-speed sampling.

In this case, it can also be said that, as a result of interference between the output signal and the reference signal, the frequency determination part 32 reduces the frequency of the output signal to a low frequency and increases the rate of change, and uses the output signal of the low frequency and the large rate of change, to thereby determine the frequency of the output signal.

Returning to FIG. 6, the A/D conversion part 316 performs A/D conversion to convert the triangular wave generated by the triangular wave generation part 315 into a digital signal. The A/D conversion part 316 is, for example, is an A/D converter.

The signal processing part 317 obtains the frequency of the triangular wave, and then obtains the frequency of the output signal based on the frequency of the triangular wave. This can be carried out by, for example, the fast Fourier transform (FFT). The FFT can be carried out, for example, by taking the digital signal converted by the A/D conversion part 316 into the PC and executing a predetermined program to perform the processing of the FFT.

In addition, not only the FFT, but also various methods can be used, such as measuring the time taken for one period of a triangular wave, or counting the number of periods of a triangular wave within a predetermined time.

Note that, in the case where the output signal is divided by the output signal division part 312, the frequency is corrected in accordance with the division ratio N.

The output part 318 outputs the obtained frequency of the output signal to the magnetic field calculation part 40.

In the above-described example, the logical operation part 314 can achieve the similar function by using a phase frequency comparator (PFC) of, not only the logic IC, but also the phase locked loop (PLL) IC. In other words, the output signal divided by the output signal division part 312 and the reference signal divided by the reference signal division part 313 are inputted to the phase frequency comparator. The phase frequency comparator compares the phases of the divided signals to obtain the phase difference, to thereby detect the digital lock. In the case where the phase difference between the divided signals is within 15 n seconds, for example, and if such a phase difference is detected three consecutive times, a digital lock is detected, and alternatively, if the phase difference is 30 n seconds or more, for example, the digital lock is released. Then, the error signal pulse of the phase frequency comparator when the digital lock is detected is used. The error signal pulse is shown in FIGS. 7B and 7E, for example.

### Second Exemplary Embodiment

Next, a second exemplary embodiment will be described. In the second exemplary embodiment, the frequency determination part 32 mixes the output signal and the reference signal to cause interference, and converts the frequency of the output signal by the superheterodyne system.

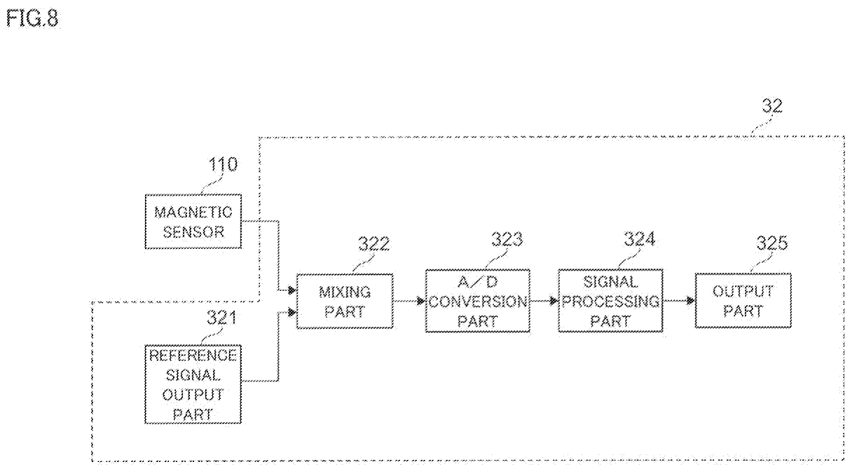

FIG. 8 shows a conceptual diagram of a circuit configuration that uses the superheterodyne system to mix the output signal and the reference signal.

The circuit configuration shown in the figure includes: a reference signal output part 321 that outputs the reference signal; a mixing part 322 that mixes the output signal and the reference signal; an A/D conversion part 323 that performs A/D conversion; a signal processing part 324 that obtains the frequency of the triangular wave; and an output part 325 that outputs the frequency.

The reference signal output part 321 outputs a reference signal at a predetermined frequency. The reference signal is generated, for example, by the clock generator. Then, as the reference signal, a clock signal with a square wave is outputted.

The mixing part 322 mixes the output signal and the reference signal. This causes the mixing part 322 to generate a mixing signal with an intermediate frequency, which is the difference between the frequency of the output signal and the frequency of the reference signal. The intermediate frequency is lower than the frequency of the output signal. In other words, the mixing by mixing part 322 causes interference between the output signal and the reference signal, which results in a low frequency of the output signal. That is, the output signal is changed to have a low frequency by the superheterodyne system. For example, in the case where the frequency of the output signal is 100 MHz and the frequency of the reference signal is 99.9 MHz, the intermediate frequency is 100 kHz.

The A/D conversion part 323 that performs A/D conversion, the signal processing part 324 that obtains the frequency of the A/D converted waveform, and the output part 325 that outputs the frequency are the same as the A/D conversion part 316, the signal processing part 317, and the output part 318 in FIG. 6. In addition, it is also possible to capture the waveform before being subjected to the A/D conversion as it is by the digital input port, and process thereof as a digital signal in the signal processing part 324. In this case, the A/D conversion part 323 is unnecessary.

Since the magnetic field signal thus obtained can reduce the frequency while maintaining the rate of change due to the interference by the superheterodyne system, the frequency change rate can increase while converting the frequency to the adequate value to be detected; therefore, it becomes possible to perform high sensitivity measurement of the minute magnetic field signal.

### Third Exemplary Embodiment

Next, a third exemplary embodiment will be described. In the third exemplary embodiment, the frequency determination part 32 utilizes the aliasing that occurs between the output signal and the reference signal to determine the frequency of the output signal.

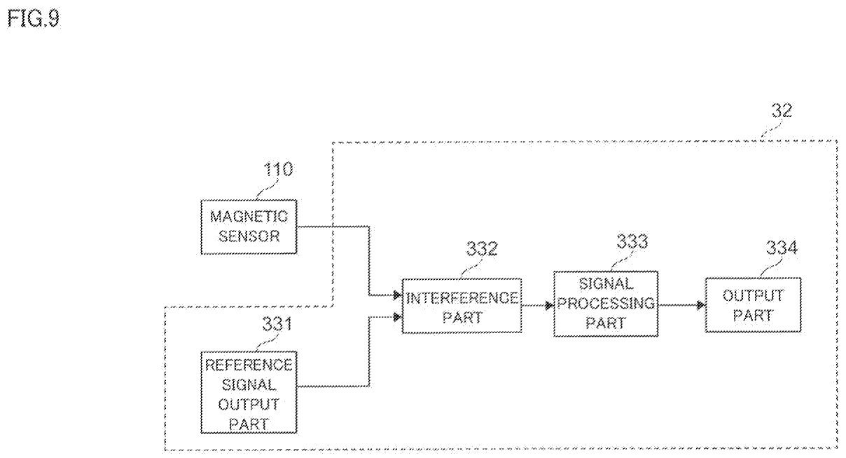

FIG. 9 shows a conceptual diagram of a circuit configuration that utilizes aliasing to determine the frequency of the output signal.

The circuit configuration shown in the figure includes: a reference signal output part 331 that outputs the reference signal; an interference part 332 that causes the output signal and the reference signal to interfere with each other to generate aliasing; a signal processing part 333 that obtains the frequency of the waveform observed by aliasing; and an output part 334 that outputs the frequency.

The reference signal output part 331 outputs a reference signal at a predetermined frequency. The reference signal is generated, for example, by the clock generator. Then, as the reference signal, a clock signal with a square wave is outputted.

Note that, similar to the first exemplary embodiment, it may be possible to provide a division part to divide at least one of the output signal and the reference signal in advance.

The interference part 332 causes the output signal and the reference signal to interfere with each other. The interference part 332 is, for example, a D-flip-flop.

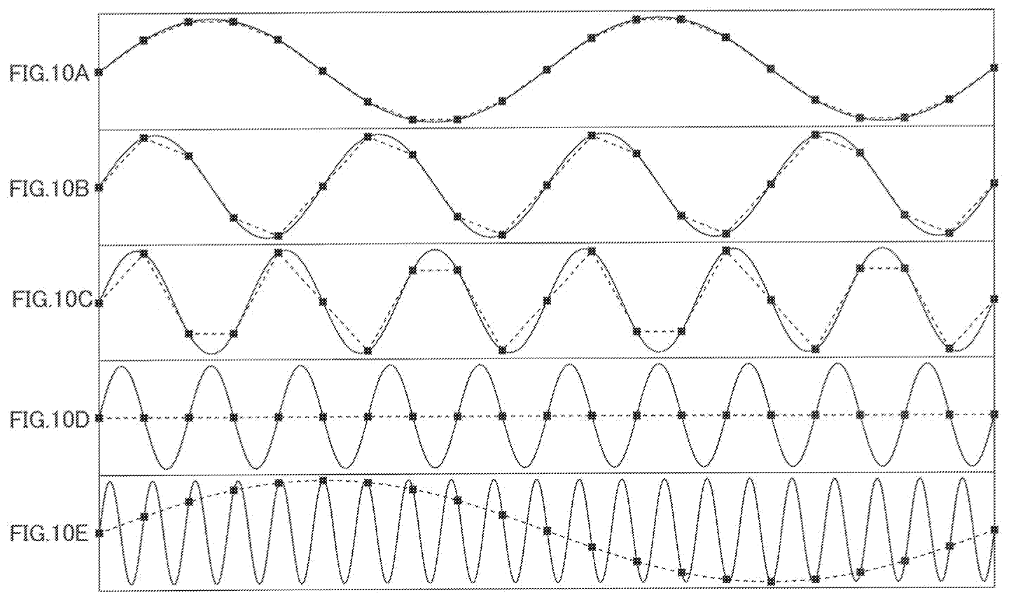

FIGS. 10A to 10E are diagrams showing the concept of aliasing taking sampling of the sine wave of an analogue signal as an example.

Here, the frequency observed when sampling a signal, which is a sine wave, is shown. In FIGS. 10A to 10E, the solid line represents the signal, and the dots on the solid line represent the points where the signal was sampled. Further, the dotted line represents the signal observed as a result of the sampling.

Of these, FIG. 10A shows the case in which the sampling frequency is larger enough than the frequency of the signal. In this case, the waveform of the signal can be measured by the sampled value.

FIGS. 10B and 10C show the case in which the frequency of the signal is larger than that in FIG. 10A and approaches the sampling frequency. However, the number of samples is larger than twice the signal frequency. In this case, the waveform cannot be reproduced accurately.

Further, FIG. 10D shows the case in which the frequency of the signal is more than those shown in FIGS. 10B and 10C, and the sampling frequency is just twice the signal frequency. The sampled value at this time is constant, and the sampled waveform does not indicate the signal frequency.

FIG. 10E shows the case in which the frequency of the signal is further larger than that in FIG. 10D, that is, the sampling frequency is less than twice the signal frequency. As a result, a waveform of a frequency that does not actually present is observed due to interference (aliasing).

The aliasing occurs when the frequency of the signal is more than ½ of the sampling frequency, as shown in FIG. 10E, and the frequency of the waveform observed by the aliasing is the difference between the frequency of the signal and the frequency of the sampling. This can also be said to be (absolute value of the observed frequency)=(frequency of the signal)−(frequency of the sampling). In other words, if the frequency of the waveform observed by the aliasing is obtained, the frequency of the signal can be obtained.

Note that the frequency of the signal is changed here; however, in practice, the interference part 332 changes the frequency of the sampling to cause aliasing. That is, the frequency of the clock signal, which is the reference signal, is changed. In this case, it can be said that the interference part 332 changes the sampling frequency for the output signal as a reference signal, to thereby cause interference.

To understand the concept of aliasing, the description was given by the analogue signal of the sine wave; however, since the digital signal causes similar aliasing, it is possible to use aliasing to measure minute frequency changes.

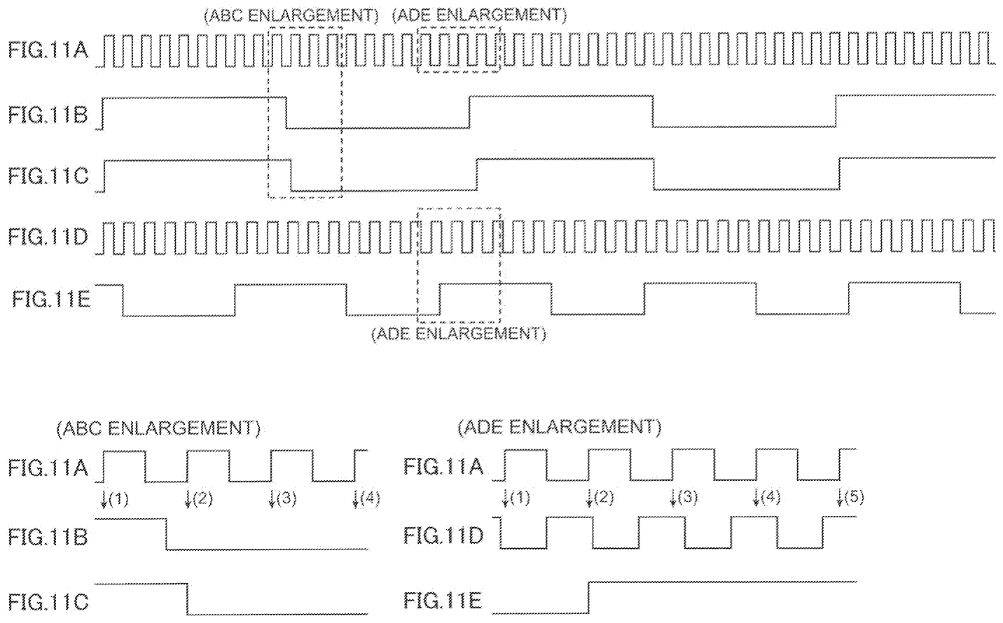

FIGS. 11A to 11E are diagrams showing the concept of aliasing used for the third exemplary embodiment taking sampling of a digital signal as an example.

Here, the frequency observed when sampling a digital signal is shown. In FIGS. 11A to 11E, the solid line represents the digital signal inputted to the interference part and the digital signal outputted from the interference part.

FIGS. 11A to 11E describe the operation in two cases: the frequency of the output signal from the magnetic sensor 110 does not cause aliasing with respect to the reference signal from the reference signal output part 331; and the frequency causes aliasing.

FIGS. 11A, 11B, and 11C show examples in which the frequency of the output signal from the magnetic sensor 110 does not cause aliasing with respect to the reference signal from the reference signal output part 331, and FIGS. 11A, 11D, and 11E show examples in which the frequency of the output signal from the magnetic sensor 110 causes aliasing with respect to the reference signal from the reference signal output part 331.

FIG. 11A shows the digital waveform of the reference signal from the reference signal output part 331.

FIG. 11B shows the digital waveform of the output signal from the magnetic sensor 110 in the example in which the frequency of the output signal from the magnetic sensor 110 does not cause aliasing with respect to the reference signal from the reference signal output part 331.

FIG. 11C shows the digital waveform of the output signal from the interference part 332 in the example in which the frequency of the output signal from the magnetic sensor 110 does not cause aliasing with respect to the reference signal from the reference signal output part 331.

FIG. 11D shows the digital waveform of the output signal from the magnetic sensor 110 in the example in which the frequency of the output signal from the magnetic sensor 110 causes aliasing with respect to the reference signal from the reference signal output part 331.

FIG. 11E shows the digital waveform of the output signal from the interference part 332 in the example in which the frequency of the output signal from the magnetic sensor 110 causes aliasing with respect to the reference signal from the reference signal output part 331.

First, description will be given of the example in which the frequency of the output signal from the magnetic sensor 110 does not cause aliasing with respect to the reference signal from the reference signal output part 331.

The interference part 332 is a D-flip-flop. The D-flip-flop inputs and outputs the digital signal. That is, signals at the logic level “H” and the logic level “L” are inputted and outputted.

Here, a D-flip-flop including three terminals, a CLK terminal, a D terminal, and a Q terminal, is used. The CLK terminal is an input terminal for the reference signal. The D-flip-flop stores the input to the D terminal at the moment when the reference signal rises. The D terminal inputs the output signal from the magnetic sensor 110 to the D-flip-flop. The Q terminal outputs the state of the logic level stored by the D-flip-flop.

The reference signal shown in FIG. 11A is outputted from the reference signal output part 331 and inputted to the CLK terminal of the D-flip-flop shown as the interference part 332. The output signal of the magnetic sensor 110 shown in FIG. 11B is inputted to the D terminal of the D-flip-flop. The output signal from the magnetic sensor 110 at the moment when the reference signal rises is stored in the D-flip-flop, and the state of the logic level thereof is outputted from the Q terminal, to thereby output the digital waveform shown in FIG. 11C.

The arrows (1) to (4) in FIG. 11 (ABC enlargement) show the timings when the reference signal in FIG. 11A rises, the output signal from the magnetic sensor 110 in FIG. 11B is stored in the D-flip-flop, and the state of the logic level is outputted from the Q terminal as an output waveform in FIG. 11C. The logic level of the output signal in FIG. 11C can change only at these timings.

In the arrow (1), since the logic level in FIG. 11B is “H,” the logic level of the output in FIG. 11C is “H.” Between the arrows (1) and (2), the logic level in FIG. 11B is inverted from “H” to “L,” but at the moment when the logic level in FIG. 11B is inverted, the logic level in FIG. 11B has not been stored yet in the D-flip-flop; accordingly, the logic level in FIG. 11C remains “H.” Thereafter, at the timing of the arrow (2), the logic level in FIG. 11B is stored in the D-flip-flop, and the logic level in FIG. 11C is inverted to “L.” After that, at the timings of the arrows (3) and (4), the logic level in FIG. 11B is stored in the D-flip-flop; however, since the logic level in FIG. 11B remains at “L,” the logic level of in FIG. 11C is maintained at “L.” In this way, in the case where frequency of the output signal of the magnetic sensor 110 is less than ½ of the frequency of the reference signal of the reference signal output part 331 and aliasing does not occur, the frequencies in FIGS. 11B and 11C are approximately the same. Due to the shift between the change in the logic level in FIG. 11B and the timing of rising of the reference signal in FIG. 11A, the timings of inversion of the logic levels in FIGS. 11B and 11C are shifted from each other, and thereby the duty of the output signal in FIG. 11C is shifted from 50%. Consequently, in the condition in which aliasing does not occur, the frequency of the output signal of the magnetic sensor 110 can be accurately measured if the frequency of the output signal is set sufficiently small with respect to the frequency of the reference signal of the reference signal output part 331. However, since there is no interference due to aliasing, the frequency change rate in the case where the output signal of the magnetic sensor 110 minutely changes is the frequency change rate of the D-flip-flop as it is, and there is no increase in the change rate.

Next, description will be given of the example in which the frequency of the output signal from the magnetic sensor 110 causes aliasing with respect to the reference signal from the reference signal output part 331.

The reference signal shown in FIG. 11A is outputted from the reference signal output part 331 and inputted to the CLK terminal of the D-flip-flop shown as the interference part 332. The output signal of the magnetic sensor 110 shown in FIG. 11D is inputted to the D terminal of the D-flip-flop. The output signal from the magnetic sensor 110 at the moment when the reference signal rises is stored in the D-flip-flop, and the state of the logic level thereof is outputted from the Q terminal, to thereby output the digital waveform shown in FIG. 11E.

The arrows (1) to (5) in FIG. 11 (ADE enlargement) show the timings when the reference signal in FIG. 11A rises, the output signal from the magnetic sensor 110 in FIG. 11D is stored in the D-flip-flop, and the state of the logic level is outputted from the Q terminal as an output waveform in FIG. 11E. The logic level of the output signal in FIG. 11E can change only at these timings.

In the arrow (1), since the logic level in FIG. 11D is “L,” the logic level of the output in FIG. 11E is “L.” Between the arrows (1) and (2), the logic level in FIG. 11D is inverted from “L” to “H,” but at the moment when the logic level in FIG. 11D is inverted, the logic level in FIG. 11D has not been stored yet in the D-flip-flop; accordingly, the logic level in FIG. 11E remains “L.”

Thereafter, at the timing of the arrow (2), the logic level in FIG. 11D is stored in the D-flip-flop, and the logic level in FIG. 11E is inverted to “H.”

The logic level in FIG. 11D is inverted from “H” to “L” between the arrows (2) and (3), and then further inverted to “H”; however, since the reference signal in FIG. 11A has not risen at the timing to read the logic level “L” during the time, the logic level “L” is not stored in the D-flip-flop. The state stored in the D-flip-flop with the arrow (3) is a logic level “H”, which is similar to the logic level “H” stored with the arrow (2); accordingly, the output of the logic level in FIG. 11E is maintained at “H.” In addition, since the same operation is repeated at the timings of the arrows (4) and (5), the output of the logic level in FIG. 11E is maintained at “H.” Since the frequency in FIG. 11A is slightly higher than the frequency in FIG. 11D, the logic level in FIG. 11D remains at “H” at any timings of the arrows (2) to (5), but the phases in FIGS. 11A and 11D continue to shift slightly from each other.

Then, when the signals in FIGS. 11A and 11D pass through the same phase, the logic level in FIG. 11D at the timing when the logic level in FIG. 11A rises becomes “L,” and the logic level in FIG. 11E is inverted to “L.” Thereafter, the logic level in FIG. 11D at the moment when the logic level in FIG. 11A rises is maintained at “L,” but the phases of the signals in FIGS. 11A and 11D continue to gradually shift from each other during that time, and when the signals in FIGS. 11A and 11D pass through the opposite phase, the logic level in FIG. 11D at the timing when the logic level in FIG. 11A rises again becomes “H,” and the logic level in FIG. 11E is inverted to “H.”

As described above, aliasing occurs when the frequency in FIG. 11D is in the range that is higher than ½ of the frequency in FIG. 11A and not more than twice the frequency of the reference signal. The interference between the signals in FIGS. 11A and 11D determines the output of the signal in FIG. 11E, and the frequency thereof is the absolute value of the frequency difference between FIGS. 11A and 11D. Accordingly, the frequency in FIG. 11E is reduced with respect to the frequency in FIG. 11D, and the smaller the frequency difference between FIGS. 11A and 11D, the lower the frequency in FIG. 11E. Moreover, in the case where the frequency of the output signal from the magnetic sensor 110 changes slightly due to the change in the external magnetic field, and a minute change occurs in the frequency in FIG. 11D, since the frequency in FIG. 11A is constant, the frequency in FIG. 11E, which is the absolute value of the difference between the frequencies in FIGS. 11A and 11D, maintains the frequency difference same as that in FIG. 11D. The frequency in FIG. 11E is reduced with respect to the frequency in FIG. 11D while the amount of change in the frequency is maintained; accordingly, the rate of change in the frequency increases.

Due to the shift between the change in the logic level in FIG. 11D and the timing of rising of the reference signal in FIG. 11A, the timing of inversion of the logic level in FIG. 11E is shifted from the timing of interference between the signals in FIGS. 11A and 11D, and thereby the duty of the output signal in FIG. 11E is shifted from 50%. Consequently, in the condition in which aliasing occurs, the frequency of the output signal of the magnetic sensor 110 can be accurately measured if the frequency of the output signal is set as close as possible to the frequency of the reference signal of the reference signal output part 331.

However, if the frequencies are too close, the interference frequency by aliasing becomes too low, and thereby the temporal resolution of the magnetic field signal detection is reduced. In addition, if the frequencies are too close, there is a problem that stable interference signals cannot be obtained due to the jitter of the frequency of the output signal from the magnetic sensor 110.

Consequently, it is preferable that the difference between the frequency of the output signal from the magnetic sensor 110 and the frequency of the reference signal of the reference signal output part 331 satisfies the temporal resolution of the magnetic field signal detection and is kept as small as possible within the range capable of obtaining the stable interference signals.

The signal processing part 333 obtains the frequency of the waveform observed by aliasing and then obtains the frequency of the output signal based on the frequency that has been obtained. This can be carried out by FFT, for example, as in the first exemplary embodiment. In addition, not only the FFT, but also various methods can be used, such as measuring the time taken for one period of the output from the interference part 332, or counting the number of periods of the output from the interference part 332 within a predetermined time, similar to the first exemplary embodiment.

### Fourth Exemplary Embodiment

Next, a fourth exemplary embodiment will be described. The basic operations are the same as those in the third exemplary embodiment, and the frequency of the output signal is determined by using aliasing that occurs between the output signal and the reference signal.

The circuit configuration is also the same as FIG. 9, but the interference part 332 utilizes the digital signal sampling function of the digital input port.

Usually, the digital input port samples at a predetermined sampling frequency or a sampling frequency that can be arbitrarily set. The mechanism is similar to that described with reference to FIGS. 11A to 11E in the third exemplary embodiment, and the input data is sampled at the timing of the sampling frequency.

Accordingly, even though the interference part 332 is not provided, if the frequency difference between the output signal of the magnetic sensor 110 and the sampling frequency causes aliasing, the interference between the frequencies causes aliasing, and thereby the frequency of the input signal is reduced, and the rate of change is increased.

To obtain a frequency difference that causes aliasing, the output signal from the magnetic sensor 110 should be divided and adjusted to be close to the sampling frequency of the digital input port.

In addition, the similar effect can also be obtained by setting the sampling frequency of the digital input port to be close to the output frequency of the magnetic sensor 110.

Moreover, it may also be possible to divide the output frequency of the magnetic sensor 110, and to set the sampling frequency of the digital input port to have a predetermined frequency.

The signal sampled at the digital input port is converted into a frequency in the signal processing part 333, and then converted into a signal magnetic field and output from the output part 334.

The fourth exemplary embodiment does not require the interference part 332; accordingly, since the device can be made compact and at a lower cost, it is suitable to configure a system that measures plural channels simultaneously.

To verify the performance of the exemplary embodiment, operations were verified by using a clock generator instead of the magnetic sensor 110 in FIG. 9. The clock generator is configured with a PLL, and generates the output frequency based on the exact clock of the crystal oscillator. Settings of an input divider, a voltage-controlled oscillator (VCO), and an output divider were adjusted to output a variety of frequencies from 270 MHz to 299.9997 MHz.

The output signal of the clock generator is subjected to sampling, data processing, and output at an FPGA. The FPGA includes the functions of the reference signal output part 331, the interference part 332, the signal processing part 333, and the output part 334. The function of the reference signal output part 331 is achieved by generating a sampling frequency by the PLL in the FPGA. The sampling frequency was set to 300 MHz. The function of the interference part 332 is achieved by sampling the input signal by the digital input port. Since the digital input port samples the input signal at the sampling frequency generated by the PLL, aliasing occurs when the frequency of the input signal is close to the sampling frequency, and the digital signal is measured at the frequency difference between both frequencies.

The frequency was measured by counting the number of sampling clocks between the rising edges of the digital signal measured at the digital input port (corresponding to one period of the measured frequency). For example, in the case where the measured frequency is 100 kHz, the time between the rising edges of the measured frequency is 10 μ seconds, during which the sampling clock of 300 MHz is counted 3000 times. The counted number is converted into the frequency by a numerical operation programmed into the FPGA, and further converted into the frequency of the input signal in consideration of aliasing (the function of the signal processing part 333). This value is shown on the display as a graph or value and is written to the external storage device (the function of the output part 334). Note that, in this case, it can be said that the interference part 332 uses the sampling clock signal at the digital signal input port to cause interference.

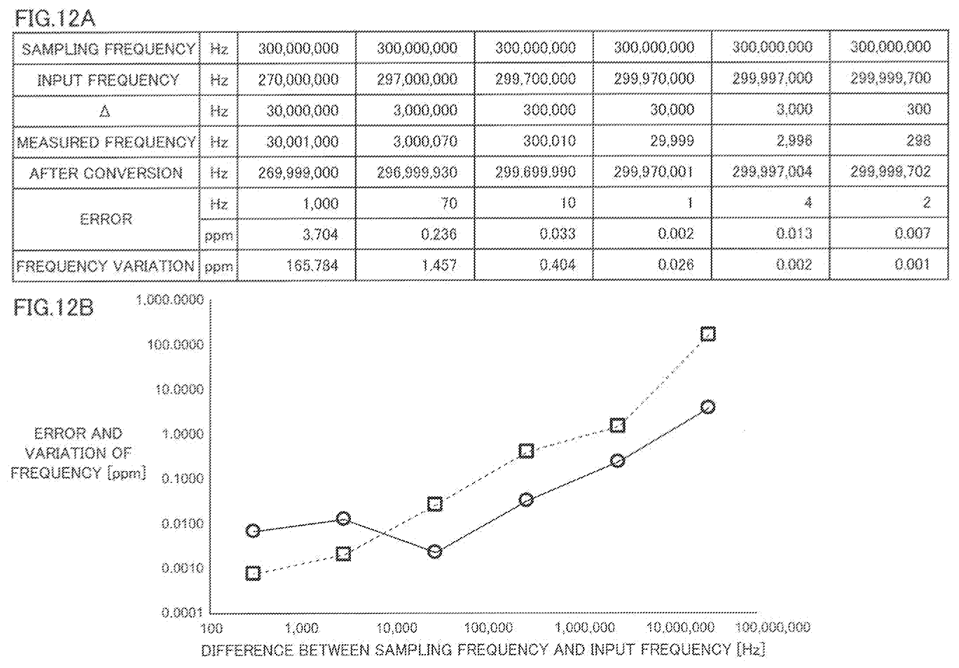

FIG. 12A shows the frequencies measured by using the above method in the case where the frequency of the input signal is changed from 270 MHz to 299.9997 MHz, and variations thereof.

The “sampling frequency” is the sampling frequency of the digital input port set by the PLL in the FPGA, the “input frequency” is the frequency of the signal inputted from the clock generator to the digital input port of the FPGA, and “Δ” is the difference between the “sampling frequency” and the “input frequency.”

The “measured frequency” is the frequency reduced by aliasing at the digital input port of the FPGA and measured, the “after conversion” is the input frequency calculated from the difference between the “sampling frequency” and the “measured frequency,” the “error” is the measurement error (Hz) calculated from the difference between the “input frequency” and the “after conversion,” and the ratio (ppm) obtained by dividing the measurement error by the “input frequency,” and the “frequency variation” is a value obtained by dividing the standard deviation of the “measured frequency” by the “input frequency.”

The frequency of the “after conversion” is approximately the same as the “input frequency,” which indicates that the frequency can be measured accurately and theoretically in the fourth exemplary embodiment.

FIG. 12B shows a graph of the error (solid line) and variation (dotted line) of the output frequency in the above measurements. A small difference between the sampling frequency and the input frequency reduces the frequency error and frequency variation, which indicates that the minute frequency difference can be measured accurately.

In the above-described first to fourth exemplary embodiments, the frequency determination part 32 reduces the frequency of the output signal to the low frequency as a result of interference between the output signal and the reference signal. This is the frequency based on the phase difference between the output signal and the reference signal. Then, the output signal of the low frequency is used to determine the frequency of the output signal. Consequently, even in the case where the output signal from the magnetic sensor 110 is a high-frequency signal of 100 MHz or higher, due to reduction to the low frequency, sufficient frequency resolution can be obtained even at the normal sampling rate. The accuracy of the frequency measurement is less likely to decrease, and the magnetic field strength can be measured more accurately. In addition, this method does not decrease the amount of change in the frequency and increases the rate of change in the frequency; accordingly, it becomes possible to measure the magnetic field with high sensitivity. Moreover, even in the case where the division is used, since the division ratio can be smaller than before, the problem of reduction in the rate of change in the frequency is less likely to occur.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. An information processing device comprising:
an obtaining part obtaining an output signal outputted by a magnetic sensor and oscillating at a frequency determined in response to strength of a magnetic field;
a frequency determination part utilizing interference between the output signal and a reference signal with a reference frequency, which is a frequency used as a reference, to determine the frequency of the output signal; and
a magnetic field calculation part calculating the strength of the magnetic field based on the determined frequency of the output signal.

2. The information processing device according to claim 1, wherein, as a result of the interference, the frequency determination part reduces the frequency of the output signal to a low frequency and uses the low frequency to determine the frequency of the output signal.

3. The information processing device according to claim 1, wherein, as a result of the interference, the frequency determination part determines the frequency of the output signal from a waveform obtained based on a phase difference between the output signal and the reference signal.

4. The information processing device according to claim 3, wherein the frequency determination part determines the frequency of the output signal based on a triangular wave generated by averaging the waveform with respect to time.

5. The information processing device according to claim 4, wherein the frequency determination part causes the output signal having been integrated and averaged and the reference signal to interfere with each other to generate the triangular wave.

6. The information processing device according to claim 4, wherein the frequency determination part uses a plurality of frequencies as the reference frequency and causes the output signal and the reference signal to interfere with each other to generate the triangular wave.

7. The information processing device according to claim 4, wherein the interference is caused by at least one of a logic operation and a phase frequency comparator.

8. The information processing device according to claim 3, wherein the frequency determination part causes the interference by mixing the output signal and the reference signal by a superheterodyne system.

9. The information processing device according to claim 1, wherein the frequency determination part utilizes aliasing caused by interference between the output signal and the reference signal to determine the frequency of the output signal.

10. The information processing device according to claim 9, wherein the frequency determination part changes a sampling frequency, as the reference signal, for the output signal to cause the interference.

11. The information processing device according to claim 9, wherein the frequency determination part uses a D-flip-flop to cause the interference.

12. The information processing device according to claim 9, wherein the frequency determination part uses a sampling clock signal at a digital signal input port to cause the interference.

13. A magnetic sensor system comprising:
a magnetic sensor including a delay generation part serially connecting a sensitive element sensing a magnetic field by a magnetic impedance effect and a capacitive element, and a potential supply part connected to the delay generation part and supplying a potential to cause an alternating current, whose frequency is set by the delay generation part, to flow to the delay generation part, the magnetic sensor outputting the alternating current as an output signal;
a frequency determination part utilizing interference between the output signal and a reference signal with a reference frequency, which is a frequency used as a reference, to determine the frequency of the output signal; and
a magnetic field calculation part calculating strength of a magnetic field based on the determined frequency of the output signal.
